(19) United States
(12) Patent Application Publication
(10) Pub. No.: US 2025/0071964 A1
(43) Pub. Date: Feb. 27, 2025

(54) STACKED TRANSISTOR MEMORY CELLS AND METHODS OF FORMING THE SAME

(71) Applicant: Taiwan Semiconductor Manufacturing Co., Ltd., Hsinchu (TW)

(72) Inventors: Tsung-Kai Chiu, Zhubei City (TW); Ting-Yun Wu, Taipei City (TW); Cheng-Yin Wang, Taipei City (TW); Szuya Liao, Zhubei City (TW)

(21) Appl. No.: 18/456,025

(22) Filed: Aug. 25, 2023

(51) Int. Cl. H10B 10/00

(52) U.S. Cl. CPC H10B 10/125

(57) ABSTRACT

In an embodiment, a device includes: a first transistor including a first gate structure; a second transistor including a second gate structure, the second gate structure disposed above and coupled to the first gate structure; a third gate structure; a fourth gate structure, the fourth gate structure disposed above and coupled to the third gate structure; a gate isolation region between the first gate structure and the third gate structure, the gate isolation region disposed between the second gate structure and the fourth gate structure; and a cross-coupling contact extending beneath the gate isolation region, the first gate structure, and the third gate structure, the cross-coupling contact coupled to the first gate structure.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example schematic of a stacked transistor, such as a complementary field-effect transistor (CFET), in a three-dimensional view, in accordance with some embodiments.

FIGS. 2-12 are views of intermediate stages in the manufacturing of CFETs, in accordance with some embodiments.

FIG. 13 is a schematic of an SRAM cell.

FIGS. 14A-14D are views of a CFET memory cell, in accordance with some embodiments.

FIGS. 15A-15B are views of a cross-coupling contact for a CFET memory cell, in accordance with some embodiments.

FIG. 16 is a three-dimensional view of a CFET memory cell, in accordance with some embodiments.

FIGS. 17A-17D are views of a CFET memory cell, in accordance with some embodiments.

FIG. 18 is a three-dimensional view of a CFET memory cell, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, complementary field-effect transistors (CFETs) are interconnected to form memory cells, such as static random-access memory (SRAM) cells. The CFETs include vertically stacked complementary nanostructure-FETs, and the SRAM cells have a four-transistor footprint, e.g., a footprint for four p-type transistors and four overlying n-type transistors. When the SRAM cell is a six-transistor SRAM cell, the regions for two of the p-type transistors in the footprint are unused. The transistors of the SRAM cells are interconnected using cross-coupling contacts that overlap the unused p-type regions. Thus, the cross-coupling contacts may overlap features in the unused p-type regions (e.g., gate electrodes) with a low risk of leakage therebetween. Interconnect complexity may thus be decreased and device scaling may thus be increased.

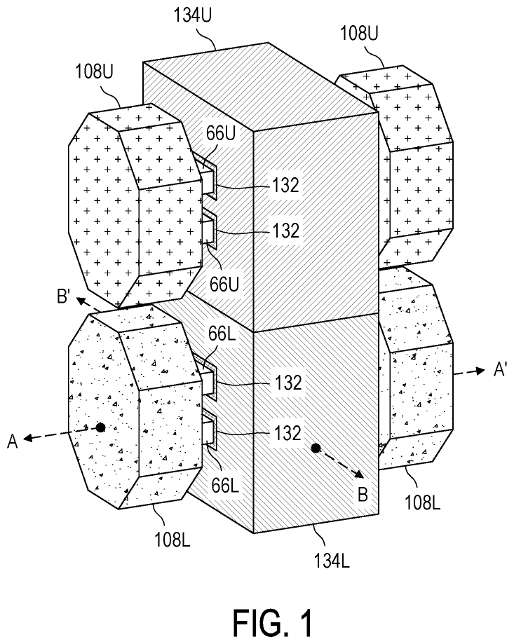

FIG. 1 illustrates an example schematic of a stacked transistor, such as a complementary field-effect transistor (CFET), in accordance with some embodiments. FIG. 1 is a three-dimensional view, where some features of the CFETs are omitted for illustration clarity.

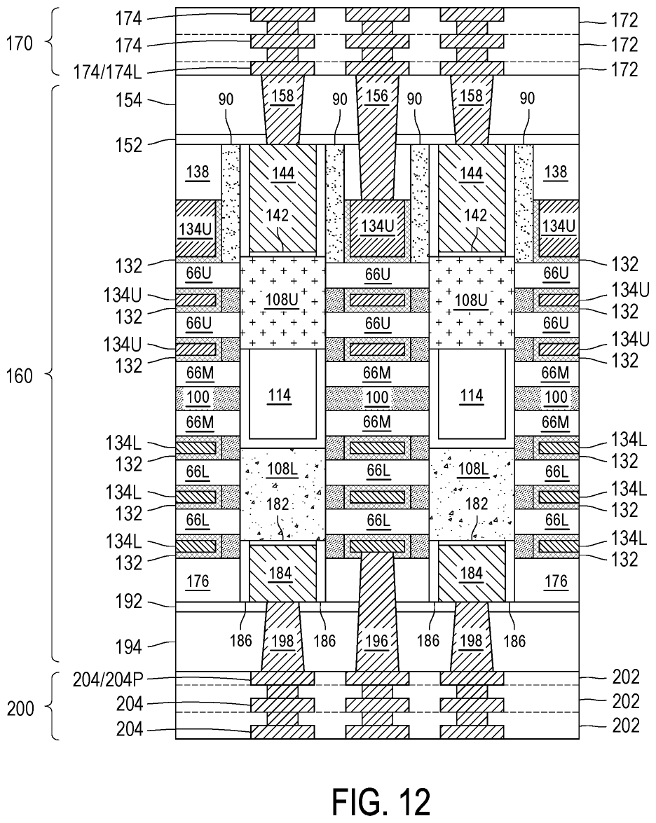

The CFETs include multiple vertically stacked nanostructure-FETs (e.g., nanowire FETs, nanosheet FETs, multi bridge channel (MBC) FETs, nanoribbon FETs, gate-all-around (GAA) FETs, or the like). For example, a CFET may include a lower nanostructure-FET of a first device type (e.g., n-type/p-type) and an upper nanostructure-FET of a second device type (e.g., p-type/n-type) that is opposite the first device type. Specifically, the CFET may include a lower PMOS transistor and an upper NMOS transistor, or the CFET may include a lower NMOS transistor and an upper PMOS transistor. Each of the nanostructure-FETs include semiconductor nanostructures 66 (including lower semiconductor nanostructures 66L and upper semiconductor nanostructures 66U), where the semiconductor nanostructures 66 act as channel regions for the nanostructure-FETs. The semiconductor nanostructures 66 may be nanosheets, nanowires, or the like. The lower semiconductor nanostructures 66L are for a lower nanostructure-FET and the upper semiconductor nanostructures 66U are for an upper nanostructure-FET. A channel isolation material (not explicitly illustrated in FIG. 1; see FIG. 12) may be used to separate and electrically isolate the upper semiconductor nanostructures 66U from the lower semiconductor nanostructures 66L.

Gate dielectrics 132 are along top surfaces, sidewalls, and bottom surfaces of the semiconductor nanostructures 66. Gate electrodes 134 (including a lower gate electrode 134L and an upper gate electrode 134U) are over the gate dielectrics 132 and around the semiconductor nanostructures 66. Source/drain regions 108 (including lower epitaxial source/drain regions 108L and upper epitaxial source/drain regions 108U) are disposed at opposing sides of the gate dielectrics 132 and the gate electrodes 134. Source/drain region(s) 108 may refer to a source or a drain, individually or collectively dependent upon the context. Isolation features may be formed to separate desired ones of the source/drain regions 108. For example, the upper epitaxial source/drain regions 108U may be separated from lower epitaxial source/drain regions 108L by one or more dielectric layers (not explicitly illustrated in FIG. 1; see FIG. 12). A lower gate electrode 134L may be coupled to an upper gate electrode 134U. Alternatively, isolation features may also be formed to separate desired ones of the gate electrodes 134. For example, a lower gate electrode 134L may be separated from an upper gate electrode 134U by an isolation layer. The isolation features between the channel regions, gates, and/or source/drain regions allow for vertically stacked transistors, thereby improving device density. Because of the vertically stacked nature of CFETs, the schematic may also be referred to as stacked transistors or folding transistors.

FIG. 1 further illustrates reference cross-sections that are used in later figures. Cross-section A-A′ is parallel to a longitudinal axis of the semiconductor nanostructures 66 of a CFET and in a direction of, for example, a current flow between the source/drain regions 108 of the CFET. Cross-section B-B′ is perpendicular to cross-section A-A′ and along a longitudinal axis of a gate electrode 134 of a CFET. Cross-section C-C′ is parallel to cross-section B-B′ and extends through the source/drain regions 108 of the CFETs. Subsequent figures refer to these reference cross-sections for clarity.

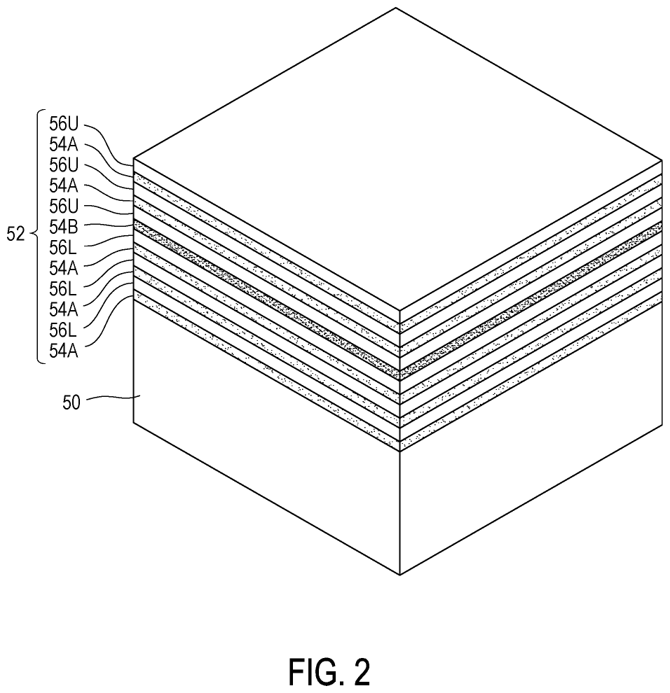

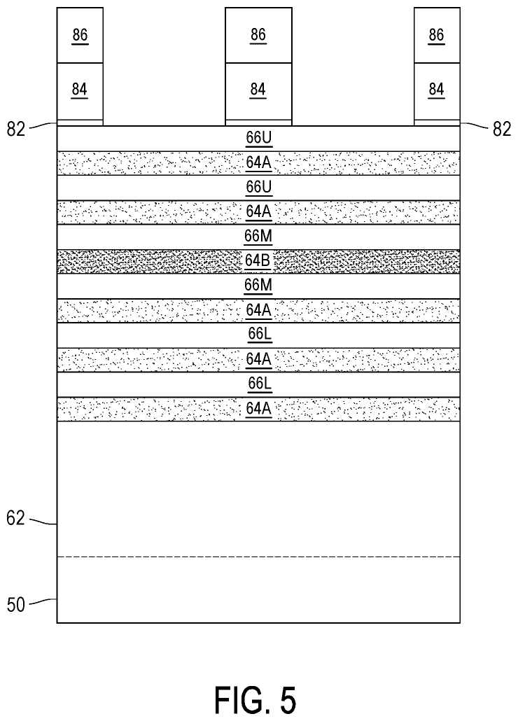

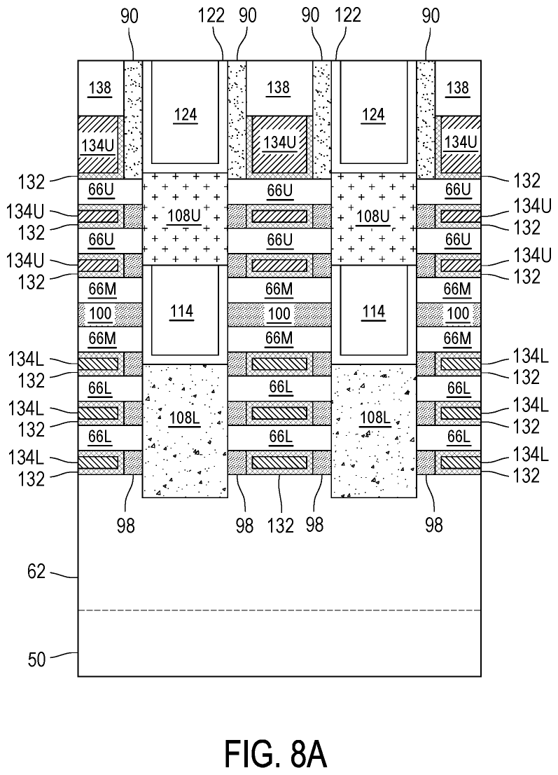

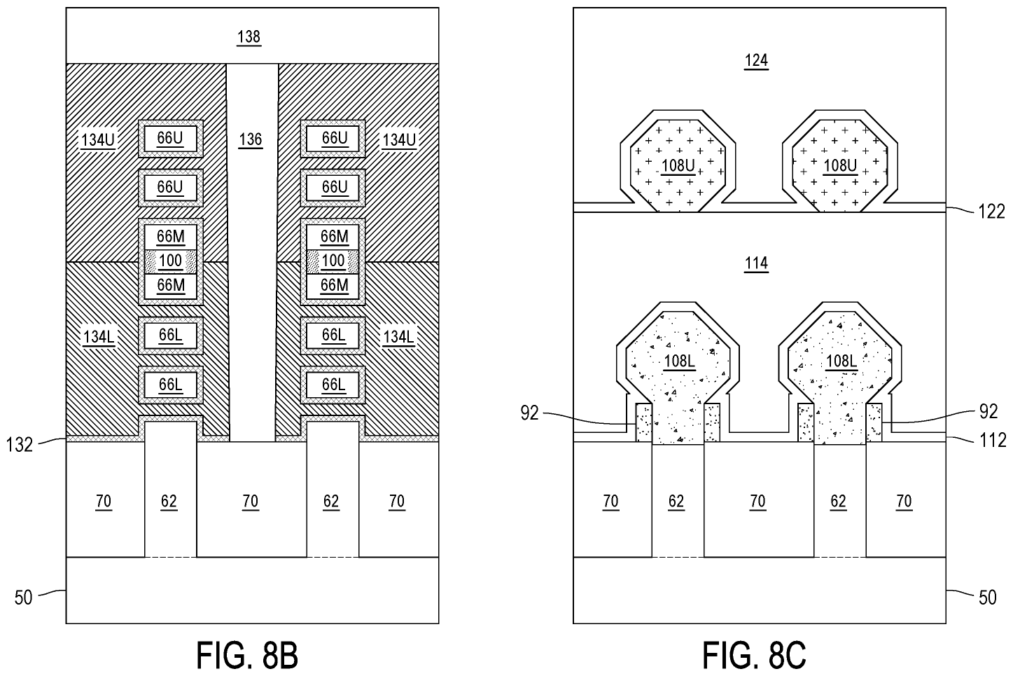

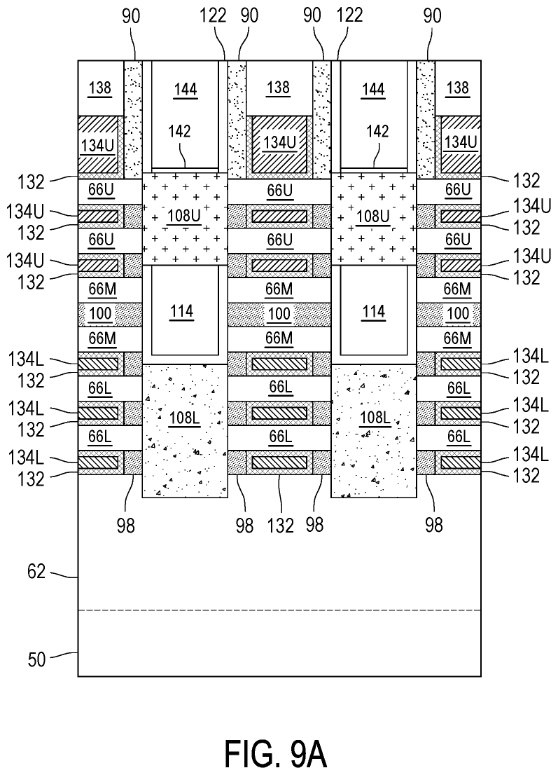

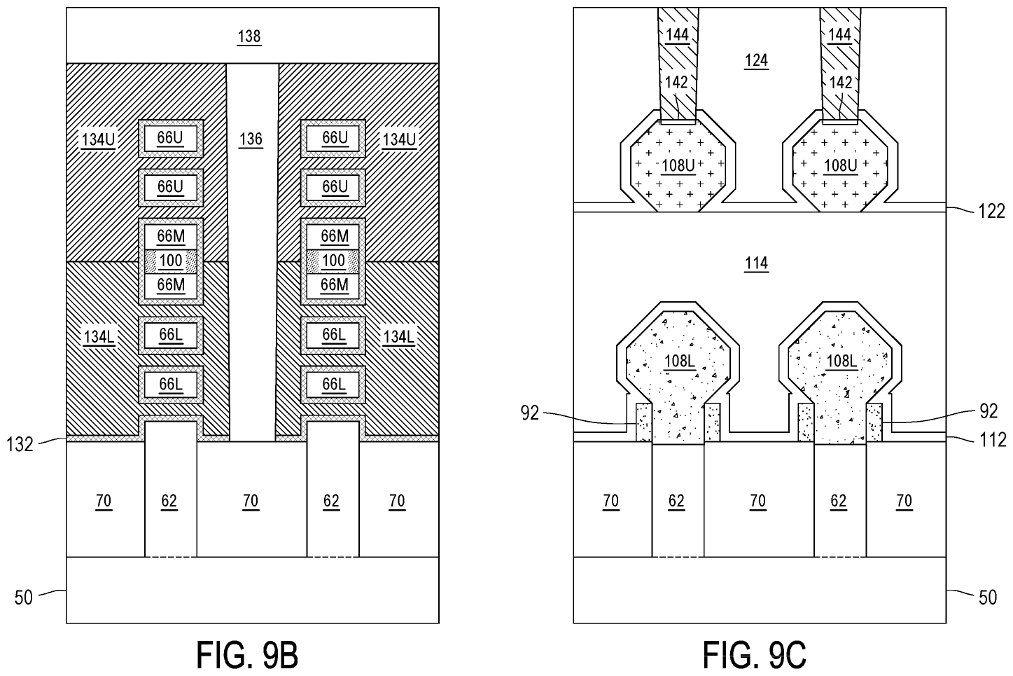

FIGS. 2-12 are views of intermediate stages in the manufacturing of CFETs, in accordance with some embodiments. FIGS. 2, 3, and 4 are three-dimensional views showing a similar three-dimensional view as FIG. 1. FIGS. 5, 6, 7, 8A, 9A, 10, 11, and 12 illustrate cross-sectional views along a similar cross-section as reference cross-section A-A′ in FIG. 1. FIGS. 8B and 9B illustrate cross-sectional views along a similar cross-section as reference cross-section B-B′ in FIG. 1. FIGS. 8C and 9C illustrate cross-sectional views along a similar cross-section as reference cross-section C-C′ in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate core, typically a silicon or glass substrate. Other substrates, such as a multi-layered or gradient substrate may also be used. In some embodiments, the semiconductor material of the substrate 50 may include silicon; germanium; a compound semiconductor including carbon-doped silicon, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. For example, the substrate 50 may be a multi-layered substrate that includes a layer of a semiconductor material formed on a silicon-germanium layer, where the silicon-germanium layer is provided on a substrate core, typically a silicon or glass substrate.

A multi-layer stack 52 is formed over the substrate 50. The multi-layer stack 52 includes alternating dummy layers 54 (including first dummy layers 54A and a second dummy layer 54B) and semiconductor layers 56 (including lower semiconductor layers 56L and upper semiconductor layers 56U). The lower semiconductor layers 56L and a lower subset of the first dummy layers 54A are disposed below the second dummy layer 54B. The upper semiconductor layers 56U and an upper subset of the first dummy layers 54A are disposed above the second dummy layer 54B. As subsequently described in greater detail, the dummy layers 54 will be removed and the semiconductor layers 56 will be patterned to form channel regions of CFETs. Specifically, the lower semiconductor layers 56L will be patterned to form channel regions of the lower nanostructure-FETs of the CFETs, and the upper semiconductor layers 56U will be patterned to form channel regions of the upper nanostructure-FETs of the CFETs.

The multi-layer stack 52 is illustrated as including a specific number of the dummy layers 54 and a specific number of the semiconductor layers 56. It should be appreciated that the multi-layer stack 52 may include any number of the dummy layers 54 and the semiconductor layers 56. Each layer of the multi-layer stack 52 may be grown by a process such as vapor phase epitaxy (VPE) or molecular beam epitaxy (MBE), deposited by a process such as chemical vapor deposition (CVD) or atomic layer deposition (ALD), or the like.

The first dummy layers 54A are formed of a first semiconductor material, and the second dummy layer 54B is formed of a second semiconductor material. The first and second semiconductor materials may be selected from the candidate semiconductor materials of the substrate 50. The first and second semiconductor materials have a high etching selectivity to one another. As such, the material of the second dummy layer 54B may be removed at a faster rate than the material of the first dummy layers 54A in subsequent processing. In some embodiments, the first dummy layers 54A are formed of silicon-germanium having a low germanium concentration (e.g., a germanium concentration in the range of 10% to 40%) and the second dummy layer 54B is formed of silicon-germanium having a high germanium concentration (e.g., a germanium concentration in the range of 40% to 50%).

The semiconductor layers 56 (including the lower semiconductor layers 56L and upper semiconductor layers 56U) are formed of one or more semiconductor material(s). The semiconductor material(s) may be selected from the candidate semiconductor materials of the substrate 50. The lower semiconductor layers 56L and the upper semiconductor layers 56U may be formed of the same semiconductor material, or may be formed of different semiconductor materials. In some embodiments, the lower semiconductor layers 56L and the upper semiconductor layers 56U are both be formed of a semiconductor material suitable for p-type devices and n-type devices, such as silicon. In some embodiments, the lower semiconductor layers 56L are formed of a semiconductor material suitable for p-type devices, such as germanium or silicon-germanium, and the upper semiconductor layers 56U are formed of a semiconductor material suitable for n-type devices, such as silicon or silicon carbide. The semiconductor material(s) of the semiconductor layers 56 have a high etching selectivity to the semiconductor materials of the dummy layers 54. As such, the materials of the dummy layers 54 may be removed at a faster rate than the material of the semiconductor layers 56 in subsequent processing. In some embodiments, the semiconductor layers 56 are formed of silicon, which may be undoped or lightly doped at this step of processing.

Some layers of the multi-layer stack 52 may be thicker than other layers of the multi-layer stack 52. The thickness of the second dummy layer 54B may be different (e.g., greater or less) than the thickness of each of the first dummy layers 54A. Additionally, the thickness of each of the semiconductor layers 56 may be different (e.g., greater or less) than the thickness(es) of each of the dummy layers 54.

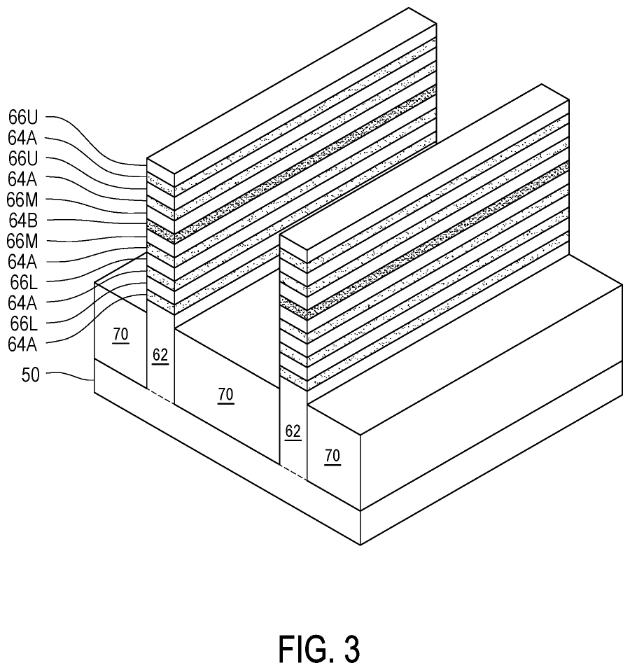

In FIG. 3, semiconductor fins 62 are formed in the substrate 50. Additionally, nanostructures 64, 66 (including first dummy nanostructures 64A, second dummy nanostructures 64B, lower semiconductor nanostructures 66L, middle semiconductor nanostructures 66M, and upper semiconductor nanostructures 66U) are formed in the multi-layer stack 52. In some embodiments, the nanostructures 64, 66 and the semiconductor fins 62 may be formed in the multi-layer stack 52 and the substrate 50, respectively, by etching trenches in the multi-layer stack 52 and the substrate 50. The etching may be any acceptable etch process, such as a reactive ion etch (RIE), neutral beam etch (NBE), the like, or a combination thereof. The etching may be anisotropic. Forming the nanostructures 64, 66 by etching the multi-layer stack 52 may define the first dummy nanostructures 64A from the first dummy layers 54A, the second dummy nanostructures 64B from the second dummy layer 54B, the lower semiconductor nanostructures 66L from some of the lower semiconductor layers 56L, the upper semiconductor nanostructures 66U from some of the upper semiconductor layers 56U, and the middle semiconductor nanostructures 66M from some of the lower semiconductor layers 56L and some of the upper semiconductor layers 56U. The first dummy nanostructures 64A and the second dummy nanostructures 64B may further be collectively referred to as the dummy nanostructures 64. The lower semiconductor nanostructures 66L and the upper semiconductor nanostructures 66U may further be collectively referred to as the semiconductor nanostructures 66.

As subsequently described in greater detail, various one of the nanostructures 64, 66 will be removed to form channel regions of CFETs. Specifically, the lower semiconductor nanostructures 66L will act as channel regions for lower nanostructure-FETs of the CFETs. Additionally, the upper semiconductor nanostructures 66U will act as channel regions for upper nanostructure-FETs of the CFETs.

The middle semiconductor nanostructures 66M are the semiconductor nanostructures 66 that are directly above/below (e.g., in contact with) the second dummy nanostructures 64B. Depending on the heights of subsequently formed source/drain regions, the middle semiconductor nanostructures 66M may or may not adjoin any source/drain regions and may or may not act as functional channel regions for the CFETs. The second dummy nanostructures 64B will be subsequently replaced with isolation structures. The isolation structures and the middle semiconductor nanostructures 66M may define boundaries of the lower nanostructure-FETs and the upper nanostructure-FETs.

The semiconductor fins 62 and the nanostructures 64, 66 may be patterned by any suitable method. For example, the semiconductor fins 62 and the nanostructures 64, 66 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the semiconductor fins 62 and the nanostructures 64, 66. In some embodiments, a mask (or other layer) may remain on the nanostructures 64, 66.

Although each of the semiconductor fins 62 and the nanostructures 64, 66 are illustrated as having a constant width throughout, in other embodiments, the semiconductor fins 62 and/or the nanostructures 64, 66 may have tapered sidewalls such that a width of each of the semiconductor fins 62 and/or the nanostructures 64, 66 continuously increases in a direction towards the substrate 50. In such embodiments, each of the nanostructures 64, 66 may have a different width and be trapezoidal in shape.

Further, isolation regions 70 are formed over the substrate 50 and between adjacent semiconductor fins 62. The isolation regions 70 may include a liner and a fill material over the liner. Each of the liner and the fill material may include a dielectric material such as an oxide (e.g., silicon oxide), a nitride (e.g., silicon nitride), the like, or a combination thereof. The formation of the isolation regions 70 may include depositing the dielectric material(s), and performing a planarization process such as a chemical mechanical polish (CMP) process, a mechanical polishing process, or the like to remove excess portions of the dielectric material(s), such as portions over the nanostructures 64, 66. The deposition processes may include ALD, high-density plasma chemical vapor deposition (HDP-CVD), flowable chemical vapor deposition (FCVD), the like, or a combination thereof. In some embodiments, the isolation regions 70 include silicon oxide formed by an FCVD process, followed by an anneal process. Then, the dielectric material(s) are recessed to define the isolation regions 70. The dielectric material(s) maybe recessed such that upper portions of the semiconductor fins 62 and the nanostructures 64, 66 extend higher than the isolation regions 70.

The previously described process is just one example of how the semiconductor fins 62 and the nanostructures 64, 66 may be formed. In some embodiments, the semiconductor fins 62 and/or the nanostructures 64, 66 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the semiconductor fins 62 and/or the nanostructures 64, 66. The epitaxial structures may comprise the previously described alternating semiconductor materials. In some embodiments where epitaxial structures are epitaxially grown, the epitaxially grown materials may be in situ doped during growth, which may obviate prior and/or subsequent implantations, although in situ and implantation doping may be used together.

Further, appropriate wells (not separately illustrated) may be formed in the semiconductor nanostructures 66. For example, an n-type impurity implant and/or a p-type impurity implant may be performed, or the semiconductor materials may be in situ doped during growth. The n-type impurities may be phosphorus, arsenic, antimony, or the like at a concentration in a range from 10¹⁷ atoms/cm³ to 10¹⁹ atoms/cm³. The p-type impurities may be boron, boron fluoride, indium, gallium, or the like at a concentration in a range from 10¹⁷ atoms/cm³ to 10¹⁹ atoms/cm³. The wells in the lower semiconductor nanostructures 66L have a conductivity type opposite from a conductivity type of lower source/drain regions that will be subsequently formed adjacent the lower semiconductor nanostructures 66L. The wells in the upper semiconductor nanostructures 66U have a conductivity type opposite from a conductivity type of upper source/drain regions that will be subsequently formed adjacent the upper semiconductor nanostructures 66U.

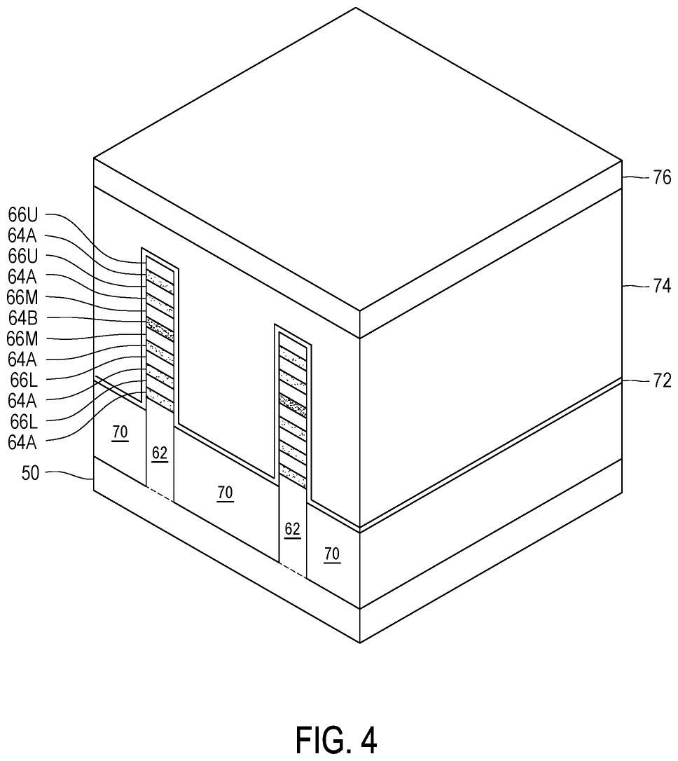

In FIG. 4, a dummy dielectric layer 72 is formed on the semiconductor fins 62 and/or the nanostructures 64, 66. The dummy dielectric layer 72 may be, for example, silicon oxide, silicon nitride, a combination thereof, or the like, and may be deposited or thermally grown according to acceptable techniques. A dummy gate layer 74 is formed over the dummy dielectric layer 72, and a mask layer 76 is formed over the dummy gate layer 74. The dummy gate layer 74 may be deposited over the dummy dielectric layer 72 and then planarized, such as by a CMP. The mask layer 76 may be deposited over the dummy gate layer 74. The dummy gate layer 74 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 74 may be deposited by physical vapor deposition (PVD), CVD, sputter deposition, or other techniques for depositing the selected material. The dummy gate layer 74 may be formed of other materials that have a high etching selectivity to insulating materials. The mask layer 76 may include, for example, silicon nitride, silicon oxynitride, or the like. In the illustrated embodiment, the dummy dielectric layer 72 covers the isolation regions 70, such that the dummy dielectric layer 72 extends between the dummy gate layer 74 and the isolation regions 70. In another embodiment, the dummy dielectric layer 72 covers only the semiconductor fins 62 and/or the nanostructures 64, 66.

In FIG. 5, the mask layer 76 may be patterned using acceptable photolithography and etching techniques to form masks 86. The pattern of the masks 86 then may be transferred to the dummy gate layer 74 and to the dummy dielectric layer 72 to form dummy gates 84 and dummy dielectrics 82, respectively. The dummy gates 84 cover respective channel regions of the nanostructures 64, 66. The pattern of the masks 86 may be used to physically separate each of the dummy gates 84 from adjacent dummy gates 84. The dummy gates 84 may also have a lengthwise direction substantially perpendicular to the lengthwise direction of respective semiconductor fins 62. The masks 86 can optionally be removed after patterning, such as by any acceptable etching technique.

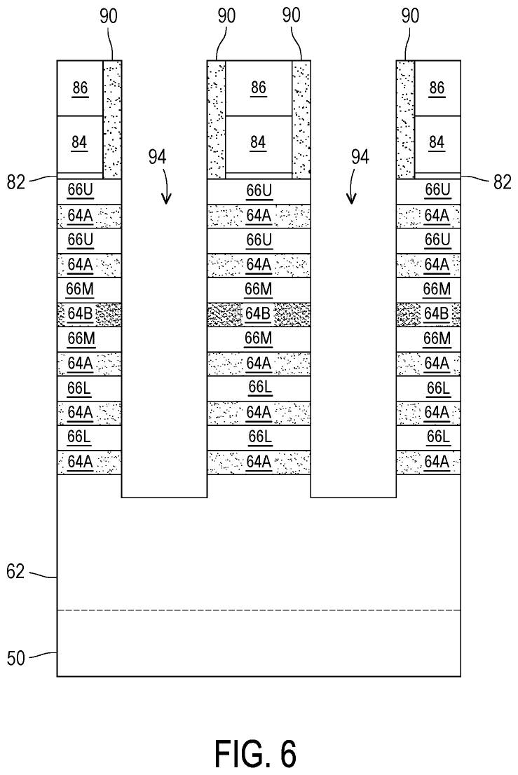

In FIG. 6, gate spacers 90 are formed over the nanostructures 64, 66 and on exposed sidewalls of the masks 86 (if present), the dummy gates 84, and the dummy dielectrics 82. The gate spacers 90 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other dielectric materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 84 (thus forming the gate spacers 90). In some embodiments, the dielectric material(s), when etched, also have portions left on the sidewalls of the semiconductor fins 62 and/or the nanostructures 64, 66 (thus forming fin spacers 92; see FIGS. 8C and 9C).

Further, implants for lightly doped source/drain (LDD) regions (not separately illustrated) may be performed. The LDD implants may be performed before the gate spacers 90 are formed. Appropriate type impurities may be implanted into the nanostructures 64, 66 to a desired depth. The LDD regions may have a same conductivity type as a conductivity type of source/drain regions that will be subsequently formed adjacent the semiconductor nanostructures 66. Additionally, the LDD regions in the lower semiconductor nanostructures 66L may have a conductivity type opposite from a conductivity type of the LDD regions in the upper semiconductor nanostructures 66U. In some embodiments, the lower semiconductor nanostructures 66L include p-type LDD regions and the upper semiconductor nanostructures 66U include n-type LDD regions. In some embodiments, the lower semiconductor nanostructures 66L include n-type LDD regions and the upper semiconductor nanostructures 66U include p-type LDD regions. The n-type impurities may be the any of the n-type impurities previously discussed, and the p-type impurities may be the any of the p-type impurities previously discussed. The lightly doped source/drain regions may have a concentration of impurities in a range from 10¹⁷ atoms/cm³ to 1020 atoms/cm³. An anneal may be used to repair implant damage and to activate the implanted impurities. In some embodiments, the grown materials of the nanostructures 64, 66 may be in situ doped during growth, which may obviate the implantations, although in situ and implantation doping may be used together.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like.

Source/drain recesses 94 are formed in the nanostructures 64, 66, the semiconductor fins 62, and the substrate 50. Epitaxial source/drain regions will be subsequently formed in the source/drain recesses 94. The source/drain recesses 94 may extend through the nanostructures 64, 66 and into the substrate 50. The semiconductor fins 62 may be etched such that bottom surfaces of the source/drain recesses 94 are disposed above, below, or level with the top surfaces of the isolation regions 70. In the illustrated example, the top surfaces of the isolation regions 70 are above the bottom surfaces of the source/drain recesses 94. The source/drain recesses 94 may be formed by etching the nanostructures 64, 66, the semiconductor fins 62, and the substrate 50 using anisotropic etching processes, such as RIE, NBE, or the like. The gate spacers 90 and the dummy gates 84 mask portions of the nanostructures 64, 66, the semiconductor fins 62, and the substrate 50 during the etching processes used to form the source/drain recesses 94. A single etch process or multiple etch processes may be used to etch each of the nanostructures 64, 66 and/or the semiconductor fins 62. Timed etch processes may be used to stop the etching of the source/drain recesses 94 after the source/drain recesses 94 reach a desired depth.

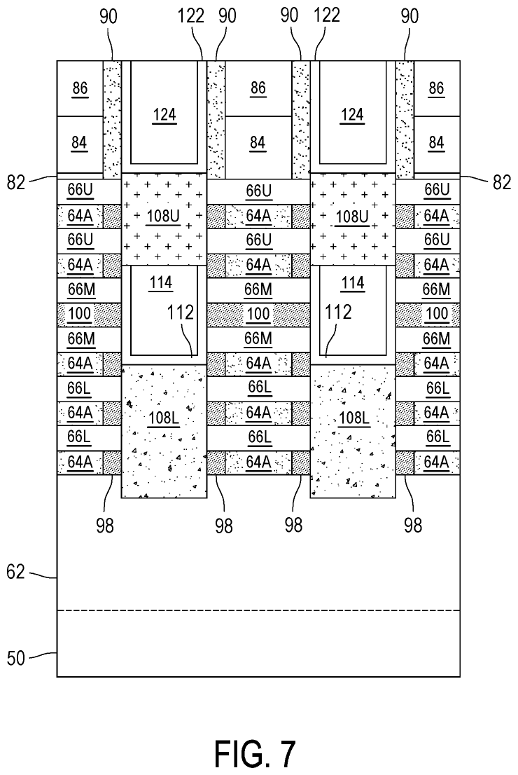

In FIG. 7, inner spacers 98 are formed on the sidewalls of the remaining portions of the first dummy nanostructures 64A. As subsequently described in greater detail, source/drain regions will be subsequently formed in the source/drain recesses 94, and the first dummy nanostructures 64A will be replaced with corresponding gate structures. The inner spacers 98 act as isolation features between the subsequently formed source/drain regions and the subsequently formed gate structures. Further, the inner spacers 98 may be used to prevent damage to the subsequently formed source/drain regions by subsequent etch processes, such as etch processes used to form gate structures. Additionally, the second dummy nanostructures 64B are replaced with isolation structures 100, which are between the middle semiconductor nanostructures 66M. The isolation structures 100 and the middle semiconductor nanostructures 66M will define the boundaries of the lower nanostructure-FETs and the upper nanostructure-FETs. The isolation structures 100 may have similar dimensions as the second dummy nanostructures 64B they replaced.

As an example to form the inner spacers 98 and the isolation structures 100, the sidewalls of the first dummy nanostructures 64A exposed by the source/drain recesses 94 are recessed to form sidewall recesses. Additionally, the second dummy nanostructures 64B are removed to form openings between the middle semiconductor nanostructures 66M, e.g., between the lower semiconductor nanostructures 66L (collectively) and the upper semiconductor nanostructures 66U (collectively). The sidewall recesses may be formed by recessing the sidewalls of the first dummy nanostructures 64A with any acceptable etch process. The etching is selective to the first dummy nanostructures 64A (e.g., selectively etches the material of the first dummy nanostructures 64A at a faster rate than the material of the semiconductor nanostructures 66). The etching may be isotropic. Although sidewalls of the first dummy nanostructures 64A are illustrated as being straight after the etching, the sidewalls may be concave or convex. The openings between the middle semiconductor nanostructures 66M may be formed by removing the second dummy nanostructures 64B with any acceptable etch process. The etching is selective to the second dummy nanostructures 64B (e.g., selectively etches the material of the second dummy nanostructures 64B at a faster rate than the material of the semiconductor nanostructures 66). The etching may be isotropic. The dummy gates 84 may adhere to and support the upper semiconductor nanostructures 66U so that the upper semiconductor nanostructures 66U do not collapse after the formation of the openings between the middle semiconductor nanostructures 66M. The middle semiconductor nanostructures 66M are exposed by the openings. In some embodiments, the etching process thins the middle semiconductor nanostructures 66M. Accordingly, the thickness of the middle semiconductor nanostructures 66M may be different (e.g., less than) the thickness of the lower semiconductor nanostructures 66L and the thickness of the upper semiconductor nanostructures 66U.

In some embodiments, the same etching process is used to recess the sidewalls of the first dummy nanostructures 64A and to remove the second dummy nanostructures 64B. For example, the second dummy nanostructures 64B may be completely removed without completely removing the first dummy nanostructures 64A, and the first dummy nanostructures 64A may be recessed without significantly recessing the semiconductor nanostructures 66. The etching process has selectivity among the materials of the first dummy nanostructures 64A, the second dummy nanostructures 64B, and the semiconductor nanostructures 66. Specifically, the etching process selectively etches the material of the first dummy nanostructures 64A at a faster rate than the material of the semiconductor nanostructures 66, and also selectively etches the material of the second dummy nanostructures 64B at a faster rate than the selectively etches the material of the first dummy nanostructures 64A. Thus, the etch rate of the first dummy nanostructures 64A is less than the etch rate of the second dummy nanostructures 64B and is greater than the etch rate of the semiconductor nanostructures 66.

An insulating material is then conformally formed in the source/drain recesses 94, the sidewall recesses, and the openings between the middle semiconductor nanostructures 66M, and subsequently etched. The insulating material may be a carbon-containing dielectric material, such as silicon oxycarbonitride, silicon oxycarbide, silicon oxynitride, or the like. Other low-dielectric constant (low-k) materials having a k-value less than about 3.5 may be utilized. The insulating material may be formed by a deposition process, such as ALD, CVD, or the like. The etching of the insulating material may be anisotropic. For example, the etch process may be a dry etch such as a RIE, a NBE, or the like. The insulating material, when etched, has portions remaining in the sidewall recesses (thus forming the inner spacers 98) and has portions remaining in the openings between the middle semiconductor nanostructures 66M (thus forming the isolation structures 100).

Although outer sidewalls of the inner spacers 98 and the isolation structures 100 are illustrated as being flush with sidewalls of the semiconductor nanostructures 66, the outer sidewalls of the inner spacers 98 and the isolation structures 100 may extend beyond or be recessed from sidewalls of the semiconductor nanostructures 66. Thus, the inner spacers 98 and the isolation structures 100 may partially fill, completely fill, or overfill the sidewall recesses and the openings between the middle semiconductor nanostructures 66M, respectively. Moreover, although the sidewalls of the inner spacers 98 and the isolation structures 100 are illustrated as being straight, those sidewalls may be concave or convex.

Next, lower epitaxial source/drain regions 108L and upper epitaxial source/drain regions 108U are formed in the source/drain recesses 94. A first contact etch stop layer (CESL) 112 and/or a first inter-layer dielectric (ILD) 114 may also be formed in the source/drain recesses 94. The first ILD 114 is between the upper epitaxial source/drain regions 108U and the lower epitaxial source/drain regions 108L. The lower epitaxial source/drain regions 108L are for lower nanostructure-FETs of the CFETs, and the upper epitaxial source/drain regions 108U are for upper nanostructure-FETs of the CFETs. The first ILD 114 thus acts as isolation regions to prevent shorting of the lower and upper nanostructure-FETs. Additionally, a second CESL 122 and/or a second ILD 124 may be formed on the upper epitaxial source/drain regions 108U.

The lower epitaxial source/drain regions 108L are in contact with the lower semiconductor nanostructures 66L and are not in contact with the upper semiconductor nanostructures 66U. In some embodiments, the lower epitaxial source/drain regions 108L exert stress in the respective channel regions of the lower semiconductor nanostructures 66L, thereby improving performance. The lower epitaxial source/drain regions 108L are formed in the source/drain recesses 94 such that each stack of the lower semiconductor nanostructures 66L is disposed between respective neighboring pairs of the lower epitaxial source/drain regions 108L. In some embodiments, the inner spacers 98 are used to separate the lower epitaxial source/drain regions 108L from the first dummy nanostructures 64A, which will be replaced with gate structures in subsequent processes.

The lower epitaxial source/drain regions 108L are epitaxially grown in the lower portions of the source/drain recesses 94. For example, the lower epitaxial source/drain regions 108L may be grown laterally from exposed sidewalls of the lower semiconductor nanostructures 66L. During the epitaxy of the lower epitaxial source/drain regions 108L, the middle semiconductor nanostructures 66M and/or the upper semiconductor nanostructures 66U may be masked to prevent undesired epitaxial growth on the middle semiconductor nanostructures 66M and/or the upper semiconductor nanostructures 66U. After the lower epitaxial source/drain regions 108L are grown, the masks on the middle semiconductor nanostructures 66M and/or the upper semiconductor nanostructures 66U may then be removed. The lower epitaxial source/drain regions 108L have a conductivity type that is suitable for the device type of the lower nanostructure-FETs. In some embodiments, the lower epitaxial source/drain regions 108L are n-type source/drain regions. For example, if the lower semiconductor nanostructures 66L are silicon, the lower epitaxial source/drain regions 108L may include materials exerting a tensile strain on the lower semiconductor nanostructures 66L, such as silicon, carbon-doped silicon, phosphorous-doped silicon, silicon phosphide, silicon arsenide, or the like. In some embodiments, the lower epitaxial source/drain regions 108L are p-type source/drain regions. For example, if the lower semiconductor nanostructures 66L are silicon-germanium, the lower epitaxial source/drain regions 108L may include materials exerting a compressive strain on the lower semiconductor nanostructures 66L, such as silicon-germanium, boron-doped silicon-germanium, boron-doped silicon, germanium, germanium tin, or the like. The lower epitaxial source/drain regions 108L may have surfaces raised from respective upper surfaces of the lower semiconductor nanostructures 66L and may have facets.

The lower epitaxial source/drain regions 108L may be implanted with dopants to form source/drain regions, similar to the process previously discussed for forming lightly-doped source/drain regions, followed by an anneal. The source/drain regions may have an impurity concentration in the range of 10¹⁹ atoms/cm³ and 10²¹ atoms/cm³. The n-type and/or p-type impurities for source/drain regions may be any of the impurities previously discussed. In some embodiments, the lower epitaxial source/drain regions 108L are in situ doped during growth.

As a result of the epitaxy processes used to form the lower epitaxial source/drain regions 108L, upper surfaces of the lower epitaxial source/drain regions 108L have facets which expand laterally outward beyond sidewalls of the nanostructures 64, 66. In some embodiments, adjacent lower epitaxial source/drain regions 108L remain separated after the epitaxy process is completed. In other embodiments, these facets cause adjacent lower epitaxial source/drain regions 108L of a same nanostructure-FET to merge. In some embodiments, fin spacers 92 (see FIG. 8C) are formed on a top surface of the isolation regions 70, thereby blocking the epitaxial growth. In some other embodiments, the fin spacers 92 may cover portions of the sidewalls of the nanostructures 64, 66 and/or the semiconductor fins 62, further blocking the epitaxial growth. In another embodiment, the spacer etch used to form the gate spacers 90 is adjusted to not form the fin spacers 92, so as to allow the lower epitaxial source/drain regions 108L to extend to the surface of the isolation regions 70.

The first ILD 114 is formed over the lower epitaxial source/drain regions 108L. The first ILD 114 may be formed of a dielectric material, which may be deposited by any suitable method, such as CVD, plasma-enhanced chemical vapor deposition (PECVD), or FCVD. Dielectric materials may include phospho-silicate glass (PSG), boro-silicate glass (BSG), boron-doped phospho-silicate glass (BPSG), undoped silicate glass (USG), or the like. Other dielectric materials formed by any acceptable process may be used.

The first CESL 112 may be formed between the first ILD 114 and the lower epitaxial source/drain regions 108L. The first CESL 112 may be formed of a dielectric material having a high etching selectivity to the dielectric material of the first ILD 114, such as silicon nitride, silicon oxide, silicon oxynitride, or the like, which may be formed by any suitable deposition process, such as CVD, ALD, or the like.

The first CESL 112 and/or the first ILD 114 may be formed by depositing a material for the first CESL 112 and depositing a material for the first ILD 114, followed by an etch-back process. In some embodiments, the first ILD 114 is initially etched, leaving the first CESL 112 unetched. An anisotropic etching process is then performed to remove the portions of the first CESL 112 that are higher than the first ILD 114. After the recessing, the sidewalls of the upper semiconductor nanostructures 66U are exposed.

In this embodiment, each source/drain recess 94 includes a lower epitaxial source/drain region 108L. In some embodiments (subsequently described), lower epitaxial source/drain regions 108L are omitted from some of the source/drain recess 94. The first ILD 114 in those source/drain recess 94 may be taller than the first ILD 114 over the epitaxial source/drain regions 108L.

The upper epitaxial source/drain regions 108U are in contact with the upper semiconductor nanostructures 66U and are not in contact with the lower semiconductor nanostructures 66L. In some embodiments, the upper epitaxial source/drain regions 108U exert stress in the respective channel regions of the upper semiconductor nanostructures 66U, thereby improving performance. The upper epitaxial source/drain regions 108U are formed in the source/drain recesses 94 such that each stack of the upper semiconductor nanostructures 66U is disposed between respective neighboring pairs of the upper epitaxial source/drain regions 108U. In some embodiments, the inner spacers 98 are used to separate the upper epitaxial source/drain regions 108U from the first dummy nanostructures 64A, which will be replaced with gate structures in subsequent processes.

The upper epitaxial source/drain regions 108U are epitaxially grown in the upper portions of the source/drain recesses 94. For example, the upper epitaxial source/drain regions 108U may be grown laterally from exposed sidewalls of the upper semiconductor nanostructures 66U. The upper epitaxial source/drain regions 108U have a conductivity type that is suitable for the device type of the upper nanostructure-FETs. The conductivity type of the upper epitaxial source/drain regions 108U may be opposite the conductivity type of the lower epitaxial source/drain regions 108L. Put another way, the upper epitaxial source/drain regions 108U may be oppositely doped from the lower epitaxial source/drain regions 108L. In some embodiments, the upper epitaxial source/drain regions 108U are n-type source/drain regions. For example, if the upper semiconductor nanostructures 66U are silicon, the upper epitaxial source/drain regions 108U may include materials exerting a tensile strain on the upper semiconductor nanostructures 66U, such as silicon, carbon-doped silicon, phosphorous-doped silicon, silicon phosphide, silicon arsenide, or the like. In some embodiments, the upper epitaxial source/drain regions 108U are p-type source/drain regions. For example, if the upper semiconductor nanostructures 66U are silicon-germanium, the upper epitaxial source/drain regions 108U may include materials exerting a compressive strain on the upper semiconductor nanostructures 66U, such as silicon-germanium, boron-doped silicon-germanium, boron-doped silicon, germanium, germanium tin, or the like. The upper epitaxial source/drain regions 108U may have surfaces raised from respective upper surfaces of the upper semiconductor nanostructures 66U and may have facets.

The upper epitaxial source/drain regions 108U may be implanted with dopants to form source/drain regions, similar to the process previously discussed for forming lightly-doped source/drain regions, followed by an anneal. The source/drain regions may have an impurity concentration in the range of 10¹⁹ atoms/cm³ and 10²¹ atoms/cm³. The n-type and/or p-type impurities for source/drain regions may be any of the impurities previously discussed. In some embodiments, the upper epitaxial source/drain regions 108U are in situ doped during growth.

As a result of the epitaxy processes used to form the upper epitaxial source/drain regions 108U, upper surfaces of the upper epitaxial source/drain regions 108U have facets which expand laterally outward beyond sidewalls of the nanostructures 64, 66. In some embodiments, adjacent upper epitaxial source/drain regions 108U remain separated after the epitaxy process is completed. In other embodiments, these facets cause adjacent upper epitaxial source/drain regions 108U of a same nanostructure-FET to merge.

The second ILD 124 is deposited over the upper epitaxial source/drain regions 108U. The second ILD 124 may be formed of a dielectric material, which may be deposited by any suitable method, such as CVD, plasma-enhanced chemical vapor deposition (PECVD), or FCVD. Dielectric materials may include phospho-silicate glass (PSG), boro-silicate glass (BSG), boron-doped phospho-silicate glass (BPSG), undoped silicate glass (USG), or the like. Other dielectric materials formed by any acceptable process may be used.

The second CESL 122 may be formed between the second ILD 124 and the upper epitaxial source/drain regions 108U. The second CESL 122 may be formed of a dielectric material having a high etching selectivity to the dielectric material of the second ILD 124, such as silicon nitride, silicon oxide, silicon oxynitride, or the like, which may be formed by any suitable deposition process, such as CVD, ALD, or the like.

The second CESL 122 and/or the second ILD 124 may be formed by depositing a material for the second CESL 122 and depositing a material for the second ILD 124. A removal process is then performed to level the top surfaces of the second ILD 124 with the top surfaces of the gate spacers 90 and the masks 86 (if present) or the dummy gates 84. In some embodiments, a planarization process such as a chemical mechanical polish (CMP), an etch-back process, combinations thereof, or the like may be utilized. The planarization process may also remove the masks 86 on the dummy gates 84, and portions of the gate spacers 90 along sidewalls of the masks 86. After the planarization process, top surfaces of the second ILD 124, the gate spacers 90, and the masks 86 (if present) or the dummy gates 84 are substantially coplanar (within process variations). Accordingly, the top surfaces of the masks 86 (if present) or the dummy gates 84 are exposed through the second ILD 124. In the illustrated embodiment, the masks 86 remain after the removal process. In other embodiments, the masks 86 are removed such that the top surfaces of the dummy gates 84 are exposed through the second ILD 124.

In FIGS. 8A-8C, the dummy gates 84 are removed in one or more etching steps, so that recesses are formed between the gate spacers 90. Portions of the dummy dielectrics 82 in the recesses are also removed. In some embodiments, the dummy gates 84 and the dummy dielectrics 82 are removed by an anisotropic dry etch process. For example, the etching process may include a dry etch process using reaction gas(es) that selectively etch the material of the dummy gates 84 at a faster rate than the materials of the second ILD 124, the isolation structures 100, the inner spacers 98, and the gate spacers 90. Each recess between the gate spacers 90 exposes and/or overlies portions of the semiconductor nanostructures 66 which act as the channel regions in the resulting devices. The portions of the semiconductor nanostructures 66 which act as the channel regions are disposed between neighboring pairs of the lower epitaxial source/drain regions 108L or between neighboring pairs of the upper epitaxial source/drain regions 108U. During the removal, the dummy dielectrics 82 may be used as etch stop layers when the dummy gates 84 are etched. The dummy dielectrics 82 may then be removed after the removal of the dummy gates 84.

The remaining portions of the first dummy nanostructures 64A are then removed to form openings in regions between the semiconductor nanostructures 66. The remaining portions of the first dummy nanostructures 64A can be removed by any acceptable etch process that selectively etches the material of the first dummy nanostructures 64A at a faster rate than the materials of the semiconductor nanostructures 66, the inner spacers 98, and the isolation structures 100. The etching may be isotropic. For example, when the first dummy nanostructures 64A are formed of silicon-germanium, the semiconductor nanostructures 66 are formed of silicon, the inner spacers 98 are formed of silicon oxycarbonitride, and the isolation structures 100 are formed of silicon oxycarbonitride, the etch process may be a wet etch using tetramethylammonium hydroxide (TMAH), ammonium hydroxide (NH₄OH), or the like. In some embodiments, a trim process (not separately illustrated) is performed to decrease the thicknesses of the exposed portions of the semiconductor nanostructures 66 and expand the openings between the semiconductor nanostructures 66.

Next, gate dielectrics 132 and gate electrodes 134 (including lower gate electrodes 134L and upper gate electrodes 134U) are formed for replacement gates. Each respective pair of a gate dielectric 132 and a gate electrode 134 (including an upper gate electrode 134U and/or a lower gate electrode 134L) may be collectively referred to as a “gate structure.” Each gate structure extends along at least three sides (e.g., a top surface, a sidewall, and a bottom surface) of a channel region of a semiconductor nanostructure 66. The gate structures may also extend along sidewalls and/or a top surface of a semiconductor fin 62.

The gate dielectrics 132 include one or more gate dielectric layer(s) disposed around the lower semiconductor nanostructures 66L, the upper semiconductor nanostructures 66U, and the isolation structures 100. Specifically, the gate dielectrics 132 are disposed on the sidewalls and/or the top surfaces of the semiconductor fins 62; on the top surfaces, the sidewalls, and the bottom surfaces of the semiconductor nanostructures 66; on the sidewalls of the inner spacers 98; and on the sidewalls of the gate spacers 90. The gate dielectrics 132 wrap around at least three sides of the semiconductor nanostructures 66. The gate dielectrics 132 may be formed of an oxide such as silicon oxide or a metal oxide, a silicate such as a metal silicate, combinations thereof, multi-layers thereof, or the like. Additionally or alternatively, the gate dielectrics 132 may be formed of a high-k dielectric material (e.g., dielectric materials having a k-value greater than about 7.0), such as a metal oxide or a silicate of hafnium, aluminum, zirconium, lanthanum, manganese, barium, titanium, lead, and combinations thereof. The dielectric material(s) of the gate dielectrics 132 may be formed by molecular-beam deposition (MBD), ALD, PECVD, or the like. Although single-layered gate dielectrics 132 are illustrated, the gate dielectrics 132 may include any number of interfacial layers and any number of main layers. For example, the gate dielectrics 132 may include an interfacial layer and an overlying high-k dielectric layer.

The lower gate electrodes 134L include one or more gate electrode layer(s) disposed over the gate dielectrics 132 and around the lower semiconductor nanostructures 66L. The lower gate electrodes 134L are disposed in the lower portions of the recesses between the gate spacers 90 and in the openings between the lower semiconductor nanostructures 66L. The lower gate electrodes 134L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 134L may include any number of work function tuning layers, any number of barrier layers, any number of glue layers, and a fill material.

The lower gate electrodes 134L are formed of material(s) that are suitable for the device type of the lower nanostructure-FETs. For example, the lower gate electrodes 134L may include one or more work function tuning layer(s) formed of work function tuning metal(s) that are suitable for the device type of the lower nanostructure-FETs. In some embodiments, the lower gate electrodes 134L include an n-type work function tuning layer, which may be formed of an n-type work function tuning metal such as titanium aluminum, titanium aluminum carbide, tantalum aluminum, tantalum carbide, combinations thereof, or the like. In some embodiments, the lower gate electrodes 134L include a p-type work function tuning layer, which may be formed of a p-type work function tuning metal such as titanium nitride, tantalum nitride, combinations thereof, or the like. Additionally or alternatively, the lower gate electrodes 134L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

The upper gate electrodes 134U include one or more gate electrode layer(s) disposed over the gate dielectrics 132 and around the upper semiconductor nanostructures 66U. The upper gate electrodes 134U are disposed in the upper portions of the recesses between the gate spacers 90 and in the openings between the upper semiconductor nanostructures 66U. The upper gate electrodes 134U may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the upper gate electrodes 134U may include any number of work function tuning layers, any number of barrier layers, any number of glue layers, and a fill material.

The upper gate electrodes 134U are formed of material(s) that are suitable for the device type of the upper nanostructure-FETs. For example, the upper gate electrodes 134U may include one or more work function tuning layer(s) formed of work function tuning metal(s) that are suitable for the device type of the upper nanostructure-FETs. In some embodiments, the upper gate electrodes 134U include an n-type work function tuning layer, which may be formed of an n-type work function tuning metal such as titanium aluminum, titanium aluminum carbide, tantalum aluminum, tantalum carbide, combinations thereof, or the like. In some embodiments, the upper gate electrodes 134U include a p-type work function tuning layer, which may be formed of a p-type work function tuning metal such as titanium nitride, tantalum nitride, combinations thereof, or the like. The work function tuning metal(s) of the upper gate electrodes 134U may be different than the work function tuning metal(s) of the lower gate electrodes 134L. Additionally or alternatively, the upper gate electrodes 134U may include a dipole-inducing element that is suitable for the device type of the upper nanostructure-FETs. Acceptable dipole-inducing elements include lanthanum, aluminum, scandium, ruthenium, zirconium, erbium, magnesium, strontium, and combinations thereof. The dipole-inducing elements the upper gate electrodes 134U may be different than the dipole-inducing elements of the lower gate electrodes 134L.

In some embodiments, isolation layers (not separately illustrated) are formed between the lower gate electrodes 134L and the upper gate electrodes 134U. The isolation layers act as isolation features between the lower gate electrodes 134L and the upper gate electrodes 134U. The isolation layers may be formed of a dielectric material. Acceptable dielectric materials may include silicon oxide, silicon nitride, silicon oxynitride, silicon oxycarbonitride, combinations thereof, or the like, which may be formed by a deposition process such as chemical vapor deposition (CVD), atomic layer deposition (ALD), or the like. Other dielectric materials formed by any acceptable process may be used. In embodiments where the isolation layers are formed, the isolation layers and the isolation structures 100 together isolate the upper gate electrodes 134U from the lower gate electrodes 134L. Accordingly, an upper nanostructure-FET may be isolated from a lower nanostructure-FET by a combination of an isolation structure 100 and an isolation layer. In some embodiments where the isolation layers are omitted, an upper nanostructure-FET may be coupled to a lower nanostructure-FET. When the isolation layers are omitted, the lower gate electrodes 134L may be physically and electrically coupled to the upper gate electrodes 134U.

As an example to form the gate structures, one or more gate dielectric layer(s) may be deposited in the recesses between the gate spacers 90 and the openings between the semiconductor nanostructures 66. The gate dielectric layer(s) may also be deposited on the top surfaces of the second ILD 124 and the gate spacers 90. Subsequently, one or more lower gate electrode layer(s) may be deposited on the gate dielectric layer(s), and in the remaining portions of the recesses between the gate spacers 90 and the openings between the semiconductor nanostructures 66. The lower gate electrode layer(s) may then be recessed. Any acceptable etch process, such as a dry etch, a wet etch, the like, or a combination thereof, may be performed to recess the lower gate electrode layer(s). The etching may be isotropic, such as an etch-back process that removes the lower gate electrode layer(s) from the upper portions of the recesses between the gate spacers 90, such that the lower gate electrode layer(s) remain in the openings between the lower semiconductor nanostructures 66L. In embodiments where the isolation layers are formed, an isolation material is conformally formed on the lower gate electrode layer(s) and then recessed. Any acceptable etch process, such as a dry etch, a wet etch, the like, or a combination thereof, may be performed to recess the isolation material. Subsequently, one or more upper gate electrode layer(s) may be deposited on the isolation material (if present) or the lower gate electrode layer(s), and in the remaining portions of the recesses between the gate spacers 90 and the openings between the upper semiconductor nanostructures 66U. A removal process is performed to remove the excess portions of the upper gate electrode layer(s), which excess portions are over the top surfaces of the gate spacers 90 and the second ILD 124, such that the upper gate electrode layer(s) remain in the openings between the upper semiconductor nanostructures 66U. In some embodiments, a planarization process such as a chemical mechanical polish (CMP), an etch-back process, combinations thereof, or the like may be utilized. The gate dielectric layer(s), after the removal process, have portions remaining in the recesses between the gate spacers 90 and the openings between the semiconductor nanostructures 66 (thus forming the gate dielectrics 132). The lower gate electrode layer(s), after the removal process, have portions left in the lower portions of the recesses between the gate spacers 90 and in the openings between the lower semiconductor nanostructures 66L (thus forming the lower gate electrodes 134L). The upper gate electrode layer(s), after the removal process, have portions left in the upper portions of the recesses between the gate spacers 90 and in the openings between the upper semiconductor nanostructures 66U (thus forming the upper gate electrodes 134U). When a planarization process is utilized, the top surfaces of the gate spacers 90, the second ILD 124, the gate dielectrics 132, and the upper gate electrodes 134U are coplanar (within process variations) after the planarization process.

Next, gate isolation regions 136 are formed to divide (or “cut”) at least some of the gate structures (including the gate dielectrics 132 and the gate electrodes 134) into multiple gate segments. As an example to form the gate isolation regions 136, openings may be patterned in desired ones of the gate structures. Any acceptable etching process, such as a dry etch, a wet etch, the like, or a combination thereof, may be performed to pattern the openings. The etching may be anisotropic. The openings expose the top surfaces of the isolation regions 70. One or more dielectric material(s) are deposited in the openings. Acceptable dielectric materials include silicon nitride, silicon oxide, silicon oxynitride, or the like, which may be formed by a deposition process such as CVD, ALD, or the like. A removal process may be performed to remove the excess portions of the dielectric material(s), which excess portions are over the top surfaces of the gate electrodes 134, thereby forming the gate isolation regions 136. In some embodiments, a planarization process such as a chemical mechanical polish (CMP), an etch-back process, combinations thereof, or the like is utilized. A gate isolation region 136 may isolate the gate structures of adjacent devices.

In some embodiments, gate masks 138 are formed over the gate structures (including the gate dielectrics 132 and the gate electrodes 134). The gate masks 138 may (or may not) also be formed over the gate spacers 90 and/or the gate isolation regions 136. Gate contacts may be subsequently formed through the gate masks 138 to contact the top surfaces of the upper gate electrodes 134U. As an example to form the gate masks 138, the gate isolation regions 136 and/or the gate structures may be recessed using any acceptable etching process. In some embodiments (not separately illustrated), the gate spacers 90 are also recessed. One or more dielectric material(s) are then conformally deposited in the recesses. The dielectric material(s) may also be deposited on the top surfaces of the second ILD 124 and the gate spacers 90. Acceptable dielectric materials may include silicon nitride, silicon carbonitride, silicon oxynitride, silicon oxycarbonitride, or the like, which may be formed by a conformal deposition process such as chemical vapor deposition (CVD), atomic layer deposition (ALD), plasma-enhanced atomic layer deposition (PEALD), or the like. Other dielectric materials formed by any acceptable process may be used. A removal process is performed to remove the excess portions of the dielectric material(s), which excess portions are over the top surfaces of the second ILD 124 and the gate spacers 90, thereby forming the gate masks 138. In some embodiments, a planarization process such as a chemical mechanical polish (CMP), an etch-back process, combinations thereof, or the like is utilized. The dielectric material(s), when planarized, have portions left in the recesses (thus forming the gate masks 138). After the planarization process, the top surfaces of the gate spacers 90, the second ILD 124, and the gate masks 138 are substantially coplanar (within process variations).

In FIGS. 9A-9C, upper source/drain contacts 144 are formed for the source/drain regions 108. The upper source/drain contacts 144 may be physically and electrically coupled to the upper epitaxial source/drain regions 108U.

As an example to form the upper source/drain contacts 144, openings for the upper source/drain contacts 144 are formed through the second ILD 124 and the second CESL 122. The openings may be formed using acceptable photolithography and etching techniques. In the illustrated embodiment, the openings are formed by a self-aligned contact (SAC) process. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A removal process may be performed to remove excess material from the top surfaces of the gate spacers 90 and the second ILD 124. The remaining liner and conductive material form the upper source/drain contacts 144 in the openings. In some embodiments, a planarization process such as a chemical mechanical polish (CMP), an etch-back process, combinations thereof, or the like is utilized. After the planarization process, the top surfaces of the gate spacers 90, the second ILD 124, the gate masks 138, and the upper source/drain contacts 144 are substantially coplanar (within process variations).

Optionally, metal-semiconductor alloy regions 142 are formed at the interfaces between the upper epitaxial source/drain regions 108U and the upper source/drain contacts 144. The metal-semiconductor alloy regions 142 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 142 can be formed before the material(s) of the upper source/drain contacts 144 by depositing a metal in the openings for the upper source/drain contacts 144 and then performing a thermal anneal process. The metal can be any metal capable of reacting with the semiconductor materials (e.g., silicon, silicon-germanium, germanium, etc.) of the upper epitaxial source/drain regions 108U to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings for the upper source/drain contacts 144, such as from surfaces of the metal-semiconductor alloy regions 142. The material(s) of the upper source/drain contacts 144 can then be formed on the metal-semiconductor alloy regions 142.

In the illustrated embodiment, the upper source/drain contacts 144 are coupled to the upper epitaxial source/drain regions 108U. In another embodiment (not separately illustrated), some of the upper source/drain contacts 144 are shared source/drain contacts that are coupled to both the upper epitaxial source/drain regions 108U and the lower epitaxial source/drain regions 108L. For example, a shared source/drain contact may be formed through an upper epitaxial source/drain region 108U, the first ILD 114, and the first CESL 112 to be coupled to a lower epitaxial source/drain region 108L. When forming such a shared source/drain contact, the opening for the shared source/drain contact may also be formed through an upper epitaxial source/drain region 108U, the first ILD 114, and the first CESL 112; additionally, a metal-semiconductor alloy region 142 may be formed on a sidewall of the upper epitaxial source/drain region 108U.

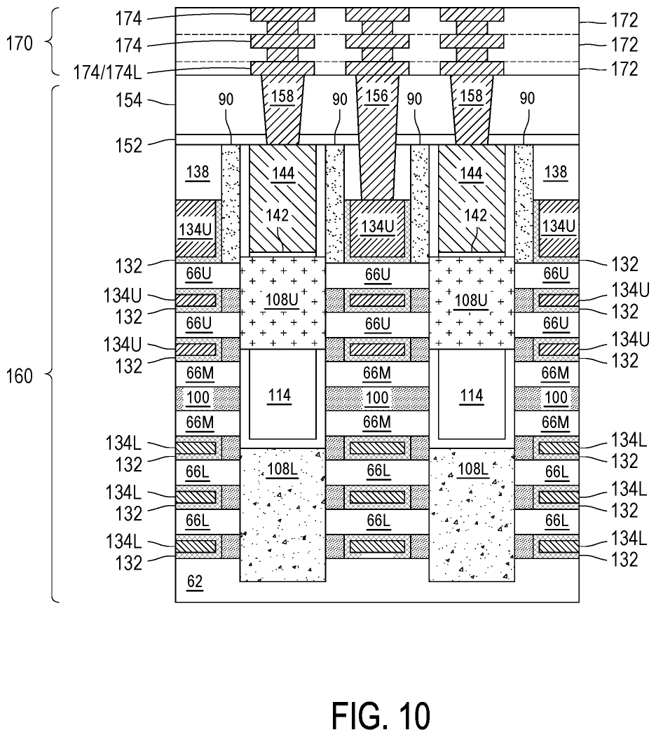

In FIG. 10, a third ILD 154 is deposited over the gate spacers 90, the second ILD 124, the gate masks 138, and the upper source/drain contacts 144. In some embodiments, the third ILD 154 is a flowable film formed by a flowable CVD method, which is subsequently cured. In some embodiments, the third ILD 154 is formed of a dielectric material such as PSG, BSG, BPSG, USG, or the like, which may be deposited by any suitable method, such as CVD, PECVD, or the like.

In some embodiments, an etch stop layer (ESL) 152 is formed between the third ILD 154 and the gate spacers 90, the second ILD 124, the gate masks 138, and the upper source/drain contacts 144. The ESL 152 may include a dielectric material having a high etching selectivity to the dielectric material of the third ILD 154, such as silicon nitride, silicon oxide, silicon oxynitride, or the like.

Upper gate contacts 156 and upper source/drain vias 158 are formed through the third ILD 154 to contact, respectively, the upper gate electrodes 134U and the upper source/drain contacts 144. The upper gate contacts 156 are also formed through the gate masks 138 (if present). The upper gate contacts 156 may be physically and electrically coupled to the upper gate electrodes 134U. The upper source/drain vias 158 may be physically and electrically coupled to the upper source/drain contacts 144.

As an example to form the upper gate contacts 156 and the upper source/drain vias 158, openings for the upper gate contacts 156 and the upper source/drain vias 158 are formed through the third ILD 154 and the ESL 152. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the third ILD 154. The remaining liner and conductive material form the upper gate contacts 156 and the upper source/drain vias 158 in the openings. The upper gate contacts 156 and the upper source/drain vias 158 may be formed in distinct processes, or may be formed in the same process. Although shown as being formed in the same cross-section, it should be appreciated that each of the upper gate contacts 156 and the upper source/drain vias 158 may be formed in different cross-sections, which may avoid shorting of the contacts.

As subsequently described in greater detail, a first interconnect structure (e.g., a front-side interconnect structure) will be formed over the substrate 50 (see FIGS. 9A-9C). Some or all of the substrate 50 will then be removed and replaced with a second interconnect structure (e.g., a back-side interconnect structure). Thus, a device layer of active devices is formed between a front-side interconnect structure and a back-side interconnect structure. The front-side and back-side interconnect structures each include conductive features that are connected to the devices of the device layer. The conductive features (e.g., interconnects) of the front-side interconnect structure will be connected to front-sides of the upper epitaxial source/drain regions 108U and the upper gate electrodes 134U to form functional circuits, such as logic circuits, memory circuits, image sensor circuits, or the like. Some of the conductive features (e.g., interconnects) of the back-side interconnect structure will be connected to back-sides of the lower epitaxial source/drain regions 108L and the lower gate electrodes 134L to form functional circuits. Additionally, some of the conductive features (e.g., power rails) of the back-side interconnect structure will be connected to back-sides of the lower epitaxial source/drain regions 108L to provide a reference voltage, supply voltage, or the like to the functional circuits. Some of the conductive features (e.g., power rails) of the front-side interconnect structure may also be connected to front-sides of the upper epitaxial source/drain regions 108U to provide a reference voltage, supply voltage, or the like.

A front-side interconnect structure 170 is formed on the device layer 160, e.g., over the third ILD 154. The front-side interconnect structure 170 is referred to as a front-side interconnect structure because it is formed at a front-side of the device layer 160 (e.g., a side of the substrate 50 on which the devices are formed). The front-side interconnect structure 170 includes dielectric layers 172 and layers of conductive features 174 in the dielectric layers 172.

The dielectric layers 172 may be formed of a dielectric material. Acceptable dielectric materials include silicon oxide, phosphosilicate glass (PSG), borosilicate glass (BSG), boron-doped phosphosilicate glass (BPSG), or the like, which may be formed by CVD, ALD, or the like. The dielectric layers 172 may be formed of a low-k dielectric material having a k-value lower than about 3.0. The dielectric layers 172 may be formed of an extra-low-k (ELK) dielectric material having a k-value of less than about 2.5.

The conductive features 174 may include conductive lines and vias. The conductive vias may extend through respective ones of the dielectric layers 172 to provide vertical connections between layers of conductive lines. The conductive features 174 may be formed by a damascene process, such as a single damascene process, a dual damascene process, or the like. In a dual damascene process, a dielectric layer 172 is patterned utilizing photolithography and etching techniques to form trenches and via openings corresponding to the desired pattern of the conductive features 174. The trenches and via openings may then be filled with a conductive material. Suitable conductive materials include copper, aluminum, tungsten, cobalt, gold, combinations thereof, or the like, which may be formed by electroplating or the like.

The front-side interconnect structure 170 includes any desired number of layers of the conductive features 174. The conductive features 174 are connected to features of the underlying devices (e.g., the upper gate electrodes 134U and the upper epitaxial source/drain regions 108U) through the upper gate contacts 156 and the upper source/drain vias 158 to form functional circuits. Thus, the conductive features 174 interconnect the upper nanostructure-FETs of the device layer 160.

After the front-side interconnect structure 170 is formed, a support substrate (not separately illustrated) may be bonded to a top surface of the front-side interconnect structure 170. The support substrate may be a glass support substrate, a ceramic support substrate, a semiconductor substrate (e.g., a silicon substrate), a wafer (e.g., a silicon wafer), or the like, which may be bonded to the front-side interconnect structure 170 by dielectric-to-dielectric bonds or the like. The support substrate may provide structural support during subsequent processing steps and in the completed device. After the support substrate is bonded to the front-side interconnect structure 170, the intermediate structure is flipped so that the back-side of the device layer 160 may be processed. The back-side of the device layer 160 refers to the side opposite to the front-side of the device layer 160 on which the front-side interconnect structure 170 is formed.

The substrate 50 is then thinned to remove at least some of the back-side portions of the substrate 50. The thinning process may include a mechanical grinding, a chemical mechanical polish (CMP), an etch back, combinations thereof, or the like. In the illustrated embodiment, the thinning process removes an entirety of the substrate 50 and portions of the semiconductor fins 62. When the substrate 50 is a multi-layered substrate, the thinning may remove the silicon-germanium layer and the substrate core, leaving only the semiconductor material that was on the silicon-germanium layer. In another embodiment, the thinning process removes only a portion of the substrate 50.

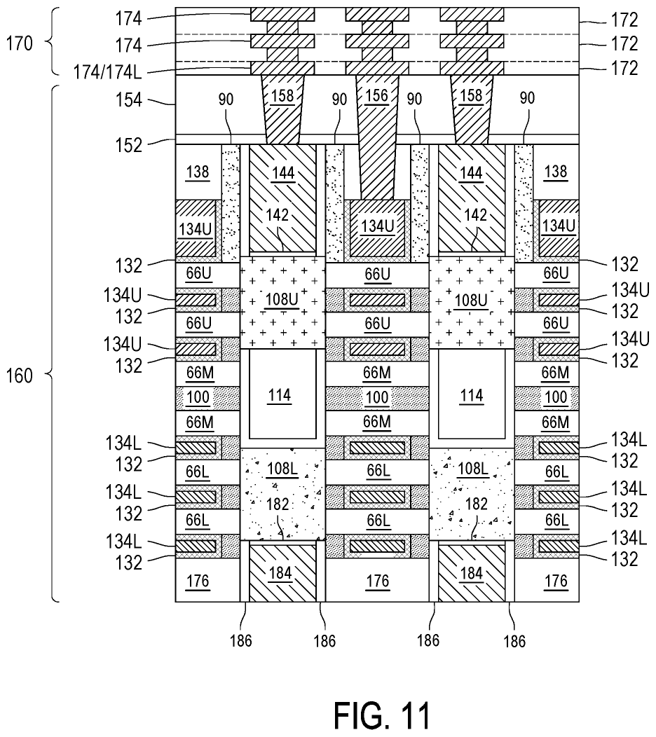

In FIG. 11, the remaining portions of the semiconductor fins 62 are optionally replaced with dielectric fins 176. Replacing the semiconductor fins 62 with the dielectric fins 176 can help reduce the parasitic capacitance and/or the leakage current of the resulting nanostructure-FETs, thereby improving their performance. The dielectric fins 176 may be formed of a low-k dielectric material, a high-k dielectric material, combinations thereof, or the like, which may be formed by thermal oxidation process, a deposition process, or the like.

As an example to form the dielectric fins 176, the semiconductor fins 62 may be removed to form recesses. The semiconductor fins 62 may be removed using acceptable photolithography and etching techniques, such as with an etching process that is selective to the semiconductor fins 62 (e.g., etches the material of the semiconductor fins 62 at a faster rate than the material of the isolation regions 70). One or more dielectric material(s) may then be formed in the recesses. The dielectric material(s) may be conformally formed in the recesses and on the back-sides of the isolation regions 70. In some embodiments, the dielectric material(s) include a liner layer of silicon nitride and a fill layer of silicon oxide. After the dielectric material(s) are deposited, a removal process is applied to remove excess dielectric material(s) over the isolation regions 70. In some embodiments, a planarization process such as a chemical mechanical polish (CMP), an etch-back process, combinations thereof, or the like may be utilized. The dielectric material(s), when planarized, have portions left in the recesses (thus forming the dielectric fins 176). After the planarization process, the bottom surfaces of the isolation regions 70 the dielectric fins 176 are substantially coplanar (within process variations).

Next, lower source/drain contacts 184 are formed for the source/drain regions 108. The lower source/drain contacts 184 may be physically and electrically coupled to the lower epitaxial source/drain regions 108L. As an example to form the lower source/drain contacts 184, openings for the lower source/drain contacts 184 are formed through the dielectric fins 176. The openings may be formed using acceptable photolithography and etching techniques. In the illustrated embodiment, the openings are formed by a self-aligned contact (SAC) process. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A removal process may be performed to remove excess material from the bottom surfaces of the dielectric fins 176. The remaining liner and conductive material form the lower source/drain contacts 184 in the openings. In some embodiments, a planarization process such as a chemical mechanical polish (CMP), an etch-back process, combinations thereof, or the like is utilized. After the planarization process, the bottom surfaces of the dielectric fins 176 and the lower source/drain contacts 184 are substantially coplanar (within process variations).

Optionally, metal-semiconductor alloy regions 182 are formed at the interfaces between the lower epitaxial source/drain regions 108L and the lower source/drain contacts 184. The metal-semiconductor alloy regions 182 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 182 can be formed before the material(s) of the lower source/drain contacts 184 by depositing a metal in the openings for the lower source/drain contacts 184 and then performing a thermal anneal process. The metal can be any metal capable of reacting with the semiconductor materials (e.g., silicon, silicon-germanium, germanium, etc.) of the lower epitaxial source/drain regions 108L to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings for the lower source/drain contacts 184, such as from surfaces of the metal-semiconductor alloy regions 182. The material(s) of the lower source/drain contacts 184 can then be formed on the metal-semiconductor alloy regions 182.

Optionally, contact spacers 186 are formed around the lower source/drain contacts 184. The contact spacers 186 may be formed by conformally depositing one or more dielectric material(s) in the contact openings for the lower source/drain contacts 184 and subsequently etching the dielectric material(s). Acceptable dielectric materials may include silicon nitride, silicon carbonitride, silicon oxynitride, silicon oxycarbonitride, or the like, which may be formed by a conformal deposition process such as chemical vapor deposition (CVD), plasma-enhanced chemical vapor deposition (PECVD), atomic layer deposition (ALD), plasma-enhanced atomic layer deposition (PEALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dielectric fins 176 (thus forming the contact spacers 186).

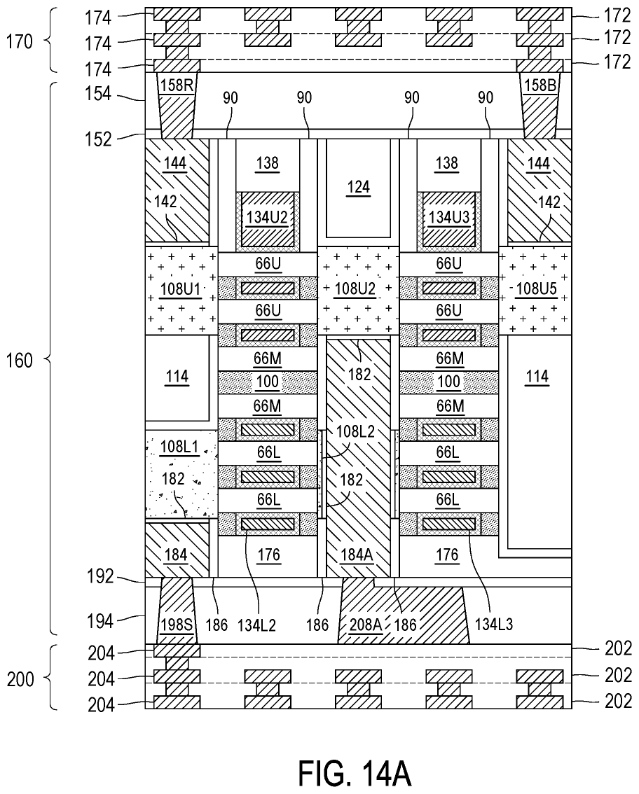

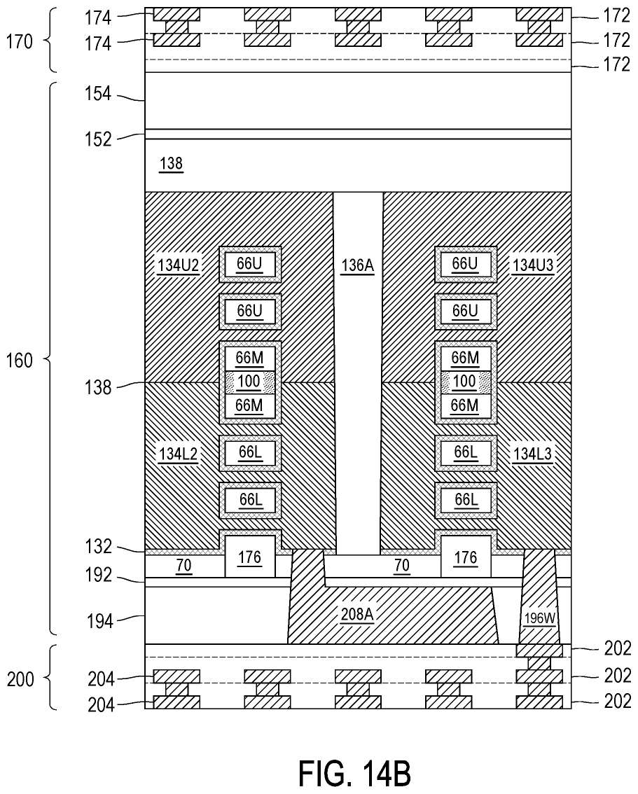

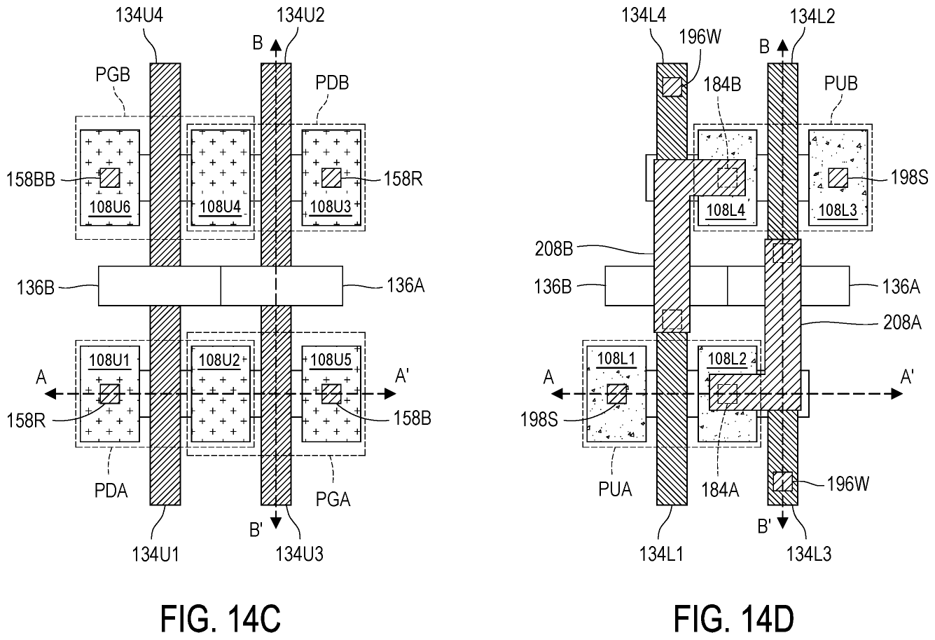

In the illustrated embodiment, the lower source/drain contacts 184 are coupled to the lower epitaxial source/drain regions 108L. In another embodiment (subsequently described for FIGS. 14A-14D), some of the lower source/drain contacts 184 are shared source/drain contacts that are coupled to both the lower epitaxial source/drain regions 108L and the upper epitaxial source/drain regions 108U. For example, a shared source/drain contact may be formed through a lower epitaxial source/drain region 108L, the first ILD 114, and the first CESL 112 to be coupled to an upper epitaxial source/drain region 108U. When forming such a shared source/drain contact, the opening for the shared source/drain contact may also be formed through a lower epitaxial source/drain region 108L, the first ILD 114, and the first CESL 112; additionally, a metal-semiconductor alloy region 182 may be formed on a sidewall of the lower epitaxial source/drain region 108L.

In FIG. 12, a fourth ILD 194 is deposited over the dielectric fins 176, the lower source/drain contacts 184, and the contact spacers 186. In some embodiments, the fourth ILD 194 is a flowable film formed by a flowable CVD method, which is subsequently cured. In some embodiments, the fourth ILD 194 is formed of a dielectric material such as PSG, BSG, BPSG, USG, or the like, which may be deposited by any suitable method, such as CVD, PECVD, or the like.

In some embodiments, an ESL 192 is formed between the fourth ILD 194 and the dielectric fins 176, the lower source/drain contacts 184, and the contact spacers 186. The ESL 192 may include a dielectric material having a high etching selectivity to the dielectric material of the fourth ILD 194, such as silicon nitride, silicon oxide, silicon oxynitride, or the like.

Lower gate contacts 196 and lower source/drain vias 198 are formed through the fourth ILD 194 to contact, respectively, the lower gate electrodes 134L and the lower source/drain contacts 184. The lower gate contacts 196 are also formed through the gate dielectrics 132 and may be formed through the dielectric fins 176 or the isolation regions 70 (not separately illustrated; see FIG. 9B). The lower gate contacts 196 may be physically and electrically coupled to the lower gate electrodes 134L. The lower source/drain vias 198 may be physically and electrically coupled to the lower source/drain contacts 184.

As an example to form the lower gate contacts 196 and the lower source/drain vias 198, openings for the lower gate contacts 196 are formed through the fourth ILD 194, the ESL 192, the gate dielectrics 132, and the dielectric fins 176 or the isolation regions 70, and openings for the lower source/drain vias 198 are formed through the fourth ILD 194 and the ESL 192. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the bottom surface of the fourth ILD 194. The remaining liner and conductive material form the lower gate contacts 196 and the lower source/drain vias 198 in the openings. The lower gate contacts 196 and the lower source/drain vias 198 may be formed in distinct processes, or may be formed in the same process. Although shown as being formed in the same cross-section, it should be appreciated that each of the lower gate contacts 196 and the lower source/drain vias 198 may be formed in different cross-sections, which may avoid shorting of the contacts.

As subsequently described for FIGS. 14A-14D, the CFETs may be interconnected to form SRAM cells. An SRAM cell includes two cross-coupled inverters. According to various embodiments, in an SRAM cell, cross-coupling contacts will be formed in addition to the lower gate contacts 196 and the lower source/drain vias 198. A cross-coupling contact is coupled to a lower gate electrode 134L and includes a conductive line that crosses a gate isolation region 136 for that lower gate electrode 134L. A cross-coupling contact may also be coupled to a lower epitaxial source/drain region 108L. The output of an inverter (e.g., a lower epitaxial source/drain region 108L) may be connected to the input of another inverter (e.g., a lower gate electrode 134L) using a cross-coupling contact. The CFETs cell may thus be interconnected to form an SRAM cell. Forming SRAM cells from CFETs may increase memory density on account of the CFETs including vertically stacked nanostructure-FETs. Cross-coupling the inverters with cross-coupling contacts may allow the CFETs to be interconnected at a lower interconnect level, improving device density.

A back-side interconnect structure 200 is formed on the device layer 160, e.g., over the fourth ILD 194. The back-side interconnect structure 200 is referred to as a back-side interconnect structure because it is formed at the back-side of the device layer 160. The back-side interconnect structure 200 includes dielectric layers 202 and layers of conductive features 204 in the dielectric layers 202.

The dielectric layers 202 may be formed of a dielectric material. Acceptable dielectric materials include silicon oxide, phosphosilicate glass (PSG), borosilicate glass (BSG), boron-doped phosphosilicate glass (BPSG), or the like, which may be formed by CVD, ALD, or the like. The dielectric layers 202 may be formed of a low-k dielectric material having a k-value lower than about 3.0. The dielectric layers 202 may be formed of an extra-low-k (ELK) dielectric material having a k-value of less than about 2.5.

The conductive features 204 may include conductive lines and vias. The conductive vias may extend through respective ones of the dielectric layers 202 to provide vertical connections between layers of conductive lines. The conductive features 204 may be formed by a damascene process, such as a single damascene process, a dual damascene process, or the like. In a dual damascene process, a dielectric layer 202 is patterned utilizing photolithography and etching techniques to form trenches and via openings corresponding to the desired pattern of the conductive features 204. The trenches and via openings may then be filled with a conductive material. Suitable conductive materials include copper, aluminum, tungsten, cobalt, gold, combinations thereof, or the like, which may be formed by electroplating or the like.

The back-side interconnect structure 200 includes any desired number of layers of the conductive features 204. Some of the conductive features 204 are connected to features of the overlying devices (e.g., the lower gate electrodes 134L and the lower epitaxial source/drain regions 108L) through the lower source/drain vias 198 and the lower gate contacts 196 to form functional circuits. Thus, the conductive features 204 interconnect the lower nanostructure-FETs of the device layer 160. Additionally, some of the conductive features 204 form a power distribution network for the devices of the device layer 160. Some or all of the conductive features 204 are power rails 204P, which are conductive lines that electrically connect the lower epitaxial source/drain regions 108L to a reference voltage, supply voltage, or the like. By placing the power rails 204P at a back-side of the device layer 160 rather than at a front-side of the device layer 160, advantages may be achieved. For example, the back-side of the device layer 160 may accommodate wider power rails than the front-side of the device layer 160, reducing resistance and increasing efficiency of power delivery to the devices of the device layer 160. For example, a width of the conductive features 204 may be at least twice a width of a first level conductive line (e.g., conductive line 174L) of the front-side interconnect structure 170.

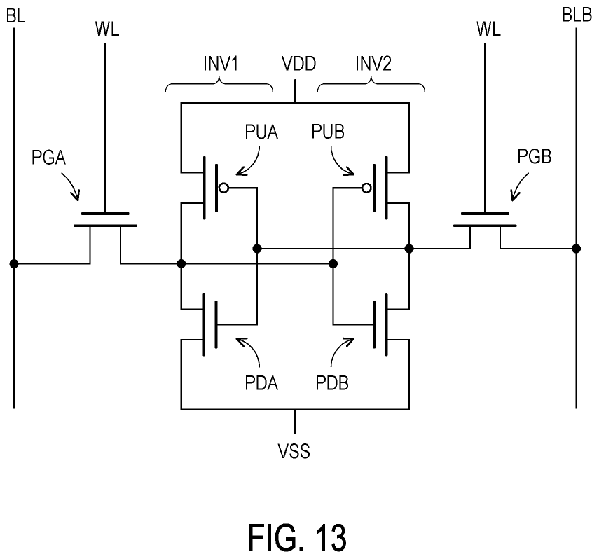

As previously noted, the CFETs may be interconnected to form SRAM cells. A schematic of an SRAM cell, specifically, a six-transistor SRAM cell, is shown in FIG. 13. The SRAM cell includes a first inverter INV1 and a second inverter INV2 cross-coupled to one another, with the output of the first inverter INV1 connected to the input of the second inverter INV2, and with the output of the second inverter INV2 connected to the input of the first inverter INV1. The first inverter INV1 includes a first pull-up transistor PUA and a first pull-down transistor PDA. The second inverter INV2 includes a second pull-up transistor PUB and a second pull-down transistor PDB. The first pull-up transistor PUA and the second pull-up transistor PUB are each coupled to a supply voltage VDD, while the first pull-down transistor PDA and the second pull-down transistor PDB are each coupled to a reference voltage VSS. The SRAM cell also includes a first pass-gate transistor PGA and a second pass-gate transistor PGB. The first pass-gate transistor PGA controls whether the output of the first inverter INV1 is coupled to a bit line BL and the second pass-gate transistor PGB controls whether the output of the second inverter INV2 is coupled to a bitbar line BLB. The first pass-gate transistor PGA and the second pass-gate transistor PGB are also coupled to and are controlled by a word line WL.

FIGS. 14A-14D are views of a CFET memory cell, in accordance with some embodiments. FIG. 14A illustrates a cross-sectional view along a similar cross-section as reference cross-section A-A′ in FIG. 1. FIG. 14B illustrates a cross-sectional view along a similar cross-section as reference cross-section B-B′ in FIG. 1. FIG. 14C illustrates a schematic top-down view of the upper nanostructure-FETs of the CFETs. FIG. 14D illustrates a schematic top-down view of the lower nanostructure-FETs of the CFETs. FIGS. 14A and 14B are shown along, respectively, reference cross-sections A-A′ and B-B′ in FIGS. 14C and 14D.

The CFET memory cell is a six-transistor SRAM cell, such as the SRAM cell described for FIG. 13. Such an SRAM cell includes four n-type transistors and two p-type transistors. The CFETs include vertically stacked complementary nanostructure-FETs. The CFETs for an SRAM cell have a four-transistor footprint, e.g., a footprint for four n-type transistors and four p-type transistors. However, only two p-type transistors are used for the SRAM cell. Thus, the regions for two of the p-type devices are unused. Lower epitaxial source/drain regions may be omitted from the source/drain recess of the unused p-type regions. Thus, the risk of neighboring bits shorting may be reduced.

Some features of the first pull-up transistor PUA, the first pull-down transistor PDA, the first pass-gate transistor PGA, and a first unused p-type region are illustrated in FIGS. 14A and 14B. It should be appreciated that the second pull-up transistor PUB, the second pull-down transistor PDB, the second pass-gate transistor PGB, and a second unused p-type region may have a similar structure as illustrated, except mirrored along the horizontal direction.

The first pull-down transistor PDA and the second pull-down transistor PDB are n-type devices. The first pull-down transistor PDA includes a first upper source/drain region 108U1, a second upper source/drain region 108U2, and a first upper gate electrode 134U1. The second pull-down transistor PDB includes a third upper source/drain region 108U3, a fourth upper source/drain region 108U4, and a second upper gate electrode 134U2. In the top-down view of the CFETs for the SRAM cell, the first pull-down transistor PDA is diagonally opposite (e.g., catty-corner) from the second pull-down transistor PDB.

The first pass-gate transistor PGA and the second pass-gate transistor PGB are n-type devices. The first pass-gate transistor PGA includes the second upper source/drain region 108U2, a fifth upper source/drain region 108U5, and a third upper gate electrode 134U3. The second pass-gate transistor PGB includes the fourth upper source/drain region 108U4, a sixth upper source/drain region 108U6, and a fourth upper gate electrode 134U4. In the top-down view of the CFETs for the SRAM cell, the first pass-gate transistor PGA is diagonally opposite (e.g., catty-corner) from the second pass-gate transistor PGB.

The first pull-up transistor PUA and the second pull-up transistor PUB are p-type devices. The first pull-up transistor PUA includes a first lower source/drain region 108L1, a second lower source/drain region 108L2, and a first lower gate electrode 134L1. The second pull-up transistor PUB includes a third lower source/drain region 108L3, a fourth lower source/drain region 108L4, and a second lower gate electrode 134L2. In the top-down view of the CFETs for the SRAM cell, the first pull-up transistor PUA is diagonally opposite (e.g., catty-corner) from the second pull-up transistor PUB.

The first and second unused regions are p-type regions. The first unused p-type region includes a third lower gate electrode 134L3. The second unused p-type region includes a fourth lower gate electrode 134L4. The third lower gate electrode 134L3 and the fourth lower gate electrode 134L4 are not parts of transistors, but are gate electrode extensions that share the same signals as the third upper gate electrode 134U3 and the fourth upper gate electrode 134U4, respectively. A gate electrode extension and underlying gate dielectric may be referred to as a gate structure extension. In the top-down view of the CFETs for the SRAM cell, the first unused p-type region is diagonally opposite (e.g., catty-corner) from the second unused p-type region.

In the illustrated embodiment, the lower nanostructure-FETs of the CFETs are p-type devices and the upper nanostructure-FETs of the CFETs are n-type devices. Accordingly, the lower nanostructure-FETs include the first pull-up transistor PUA and the second pull-up transistor PUB, while the upper nanostructure-FETs include the first pull-down transistor PDA, the second pull-down transistor PDB, the first pass-gate transistor PGA, and the second pass-gate transistor PGB. Further, the first pull-down transistor PDA and the second pull-down transistor PDB are vertically stacked over the first pull-up transistor PUA and the second pull-up transistor PUB, respectively. Thus, the source/drain regions of the first pull-down transistor PDA and the first pull-up transistor PUA are formed in the same source/drain recesses, and the source/drain regions of the second pull-down transistor PDB and the second pull-up transistor PUB are formed in the same source/drain recesses. Further, the first upper gate electrode 134U1 of the first pull-down transistor PDA is physically and electrically coupled to the first lower gate electrode 134L1 of the first pull-up transistor PUA, and the second upper gate electrode 134U2 of the second pull-down transistor PDB is physically and electrically coupled to the second lower gate electrode 134L2 of the second pull-up transistor PUB. The first pass-gate transistor PGA and the second pass-gate transistor PBB are vertically stacked over the unused p-type regions. Further, the third upper gate electrode 134U3 of the first pass-gate transistor PGA is physically and electrically coupled to the third lower gate electrode 134L3, and the fourth upper gate electrode 134U4 of the second pass-gate transistor PGB is physically and electrically coupled to the fourth lower gate electrode 134L4. The third lower gate electrode 134L3 and the fourth lower gate electrode 134L4 are gate electrode extensions for, respectively, the third upper gate electrode 134U3 and the fourth upper gate electrode 134U4. The gate electrode extensions function as conductive lines, which will be used to connect the third upper gate electrode 134U3 and the fourth upper gate electrode 134U4 to underlying contacts (subsequently described).

The conductive features 174 of the front-side interconnect structure 170 include reference voltage interconnects, bit line interconnects, and bitbar line interconnects. The upper source/drain vias 158 include reference voltage vias 158R that couple the reference voltage interconnects to the first upper source/drain region 108U1 and to the third upper source/drain region 108U3 (through respective upper source/drain contacts 144). Additionally, the upper source/drain vias 158 include a bit line via 158B that couples the bit line interconnects to the to the fifth upper source/drain region 108U5 (through an upper source/drain contact 144). Further, the upper source/drain vias 158 include a bitbar line via 158BB that couples the bitbar line interconnects to the to the sixth upper source/drain region 108U6 (through an upper source/drain contact 144).

The conductive features 204 of the back-side interconnect structure 200 include supply voltage interconnects and word line interconnects. The lower source/drain vias 198 include supply voltage vias 198S that couple the supply voltage interconnects to the first lower source/drain region 108L1 and to the third lower source/drain region 108L3 (through respective lower source/drain contacts 184). The lower gate contacts 196 include word line contacts 196W that couple the word line interconnects to the third upper gate electrode 134U3 (through the third lower gate electrode 134L3) and to the fourth upper gate electrode 134U4 (through the fourth lower gate electrode 134L4).

As previously noted, some of the lower source/drain contacts 184 may be coupled to both the lower epitaxial source/drain regions 108L and the upper epitaxial source/drain regions 108U. In the CFETs for the memory cell, a first shared source/drain contact 184A is coupled to the second lower source/drain region 108L2 of the first pull-up transistor PUA, and is also coupled to the second upper source/drain region 108U2 of the first pull-down transistor PDA and the first pass-gate transistor PGA. Thus, the first shared source/drain contact 184A is the output of the first inverter INV1 (see FIG. 13). Also in the CFETs for the memory cell, a second shared source/drain contact 184B is coupled to the fourth lower source/drain region 108L4 of the second pull-up transistor PUB, and is also coupled to the fourth upper source/drain region 108U4 of the second pull-down transistor PDB and the second pass-gate transistor PGB. Thus, the second shared source/drain contact 184B is the output of the second inverter INV2 (see FIG. 13).

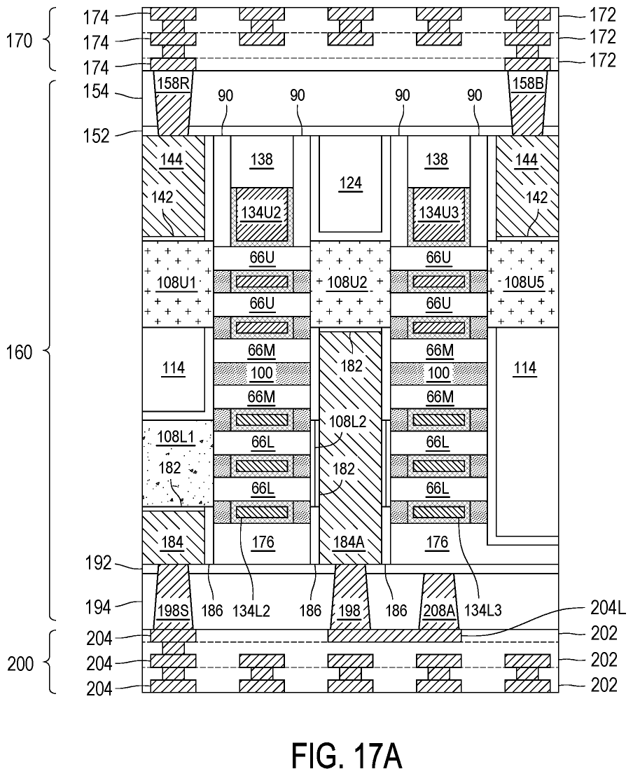

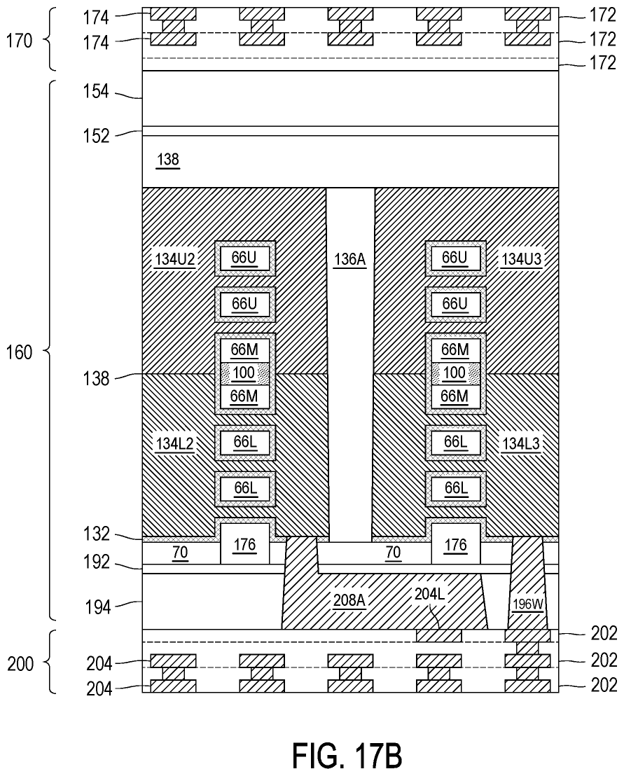

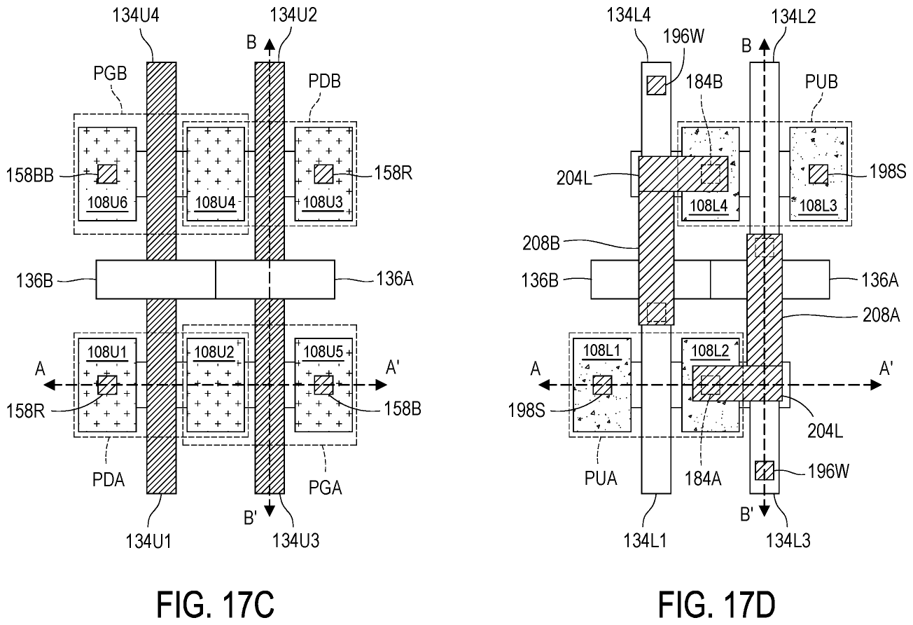

The first inverter INV1 and the second inverter INV2 (see FIG. 13) are cross-coupled using cross-coupling contacts 208, which are disposed at the back-side of the device layer 160 instead of the front-side of the device layer 160. The cross-coupling contacts 208 are coupled to respective lower gate electrodes 134L, and extend across respective gate isolation regions 136 that are adjacent to the lower gate electrodes 134L, thereby laterally offsetting the contacts to the lower gate electrodes 134L. In this embodiments, the cross-coupling contacts 208 are also coupled to respective lower epitaxial source/drain regions 108L (through a lower source/drain contact 184). Each cross-coupling contact 208 is L-shaped in a top-down view, where one end of the L-shaped contact is coupled to a lower gate electrode 134L and another end of the L-shaped contact is coupled to a lower source/drain contact 184. An L-shaped cross-coupling contact 208 has a first segment extending in a first direction (e.g., the vertical direction in the top-down views, which is parallel to the longitudinal axes of the gate structures) and has a second segment extending in a second direction (e.g., the horizontal direction in the top-down views, which is perpendicular to the longitudinal axes of the gate structures), where the second direction is perpendicular to the first direction. In another embodiment (subsequently described for FIGS. 17A-17D), the cross-coupling contacts 208 are coupled to respective lower epitaxial source/drain regions 108L through first level conductive lines of the back-side interconnect structure 200. The cross-coupling contacts 208 for each memory cell include a first cross-coupling contact 208A and a second cross-coupling contact 208B.

The first cross-coupling contact 208A is coupled to the second lower gate electrode 134L2 of the second pull-up transistor PUB and to the second upper gate electrode 134U2 of the second pull-down transistor PDB (through the second lower gate electrode 134L2). Thus, the first cross-coupling contact 208A is the input of the second inverter INV2 (see FIG. 13). The first cross-coupling contact 208A extends beneath a first gate isolation region 136A, in a direction parallel to the longitudinal axis of the second lower gate electrode 134L2. The first gate isolation region 136A is between the second lower gate electrode 134L2 and the third lower gate electrode 134L3, and is also between the second upper gate electrode 134U2 and the third upper gate electrode 134U3. Because the first cross-coupling contact 208A is formed at the back-side of the device layer 160, the first cross-coupling contact 208A extends beneath and along an unused p-type region, e.g., the third lower gate electrode 134L3. Because the gate isolation regions 70 and the dielectric fins 176 are between the third lower gate electrode 134L3 and the first cross-coupling contact 208A, the first cross-coupling contact 208A may overlap and be formed along the third lower gate electrode 134L3 with a low risk of leakage between the first cross-coupling contact 208A and the third lower gate electrode 134L3. The third lower gate electrode 134L3 overlaps the first cross-coupling contact 208A in a top-down view. Accordingly, the input of the second inverter INV2 (e.g., the first cross-coupling contact 208A) may be laterally offset so that its end is disposed close to the output of the first inverter INV1 (e.g., the first shared source/drain contact 184A), which may decrease interconnect complexity and increase device scaling, without reducing device performance. In this embodiment, the first cross-coupling contact 208A is L-shaped, and is also coupled to the first shared source/drain contact 184A.

The second cross-coupling contact 208B is coupled to the first lower gate electrode 134L1 of the first pull-up transistor PUA and to the first upper gate electrode 134U1 of the first pull-down transistor PDA (through the first lower gate electrode 134L1). Thus, the second cross-coupling contact 208B is the input of the first inverter INV1 (see FIG. 13). The second cross-coupling contact 208B extends beneath a second gate isolation region 136B, in a direction parallel to the longitudinal axis of the first lower gate electrode 134L1. The second gate isolation region 136B is between the first lower gate electrode 134L1 and the fourth lower gate electrode 134L4, and is also between the first upper gate electrode 134U1 and the fourth upper gate electrode 134U4. Because the second cross-coupling contact 208B is formed at the back-side of the device layer 160, the second cross-coupling contact 208B extends beneath and along an unused p-type region, e.g., the fourth lower gate electrode 134L4. Because the gate isolation regions 70 and the dielectric fins 176 are between the fourth lower gate electrode 134L4 and the second cross-coupling contact 208B, the second cross-coupling contact 208B may overlap and be formed along the fourth lower gate electrode 134L4 with a low risk of leakage between the second cross-coupling contact 208B and the fourth lower gate electrode 134L4. The fourth lower gate electrode 134L4 overlaps the second cross-coupling contact 208B in a top-down view. Accordingly, the input of the first inverter INV1 (e.g., the second cross-coupling contact 208B) may be laterally offset so that its end is disposed close to the output of the second inverter INV2 (e.g., the second shared source/drain contact 184B), which may decrease interconnect complexity and increase device scaling, without reducing device performance. In this embodiment, the second cross-coupling contact 208B is L-shaped, and is also coupled to the second shared source/drain contact 184B.

In another embodiment (not separately illustrated), the lower nanostructure-FETs of the CFETs are n-type devices and the upper nanostructure-FETs of the CFETs are p-type devices. Accordingly, the upper nanostructure-FETs include the first pull-up transistor PUA and the second pull-up transistor PUB, while the lower nanostructure-FETs include the first pull-down transistor PDA, the second pull-down transistor PDB, the first pass-gate transistor PGA, and the second pass-gate transistor PGB. The vertical stacking of the gate electrodes and the source/drain regions may be inverted from the previously described vertical stacking. The gate electrode extensions are above the gate electrodes of the first pass-gate transistor PGA and the second pass-gate transistor PGB. Additionally, the conductive features 204 of the back-side interconnect structure 200 include reference voltage interconnects, bit line interconnects, and bitbar line interconnects, while the lower source/drain vias 198 include reference voltage vias, bit line vias, and bitbar line vias for the respective interconnects. Further, the conductive features 174 of the front-side interconnect structure 170 include supply voltage interconnects, while the upper source/drain vias 158 include supply voltage vias for the respective interconnects. The word line interconnects may be in the front-side interconnect structure 170 or may be in the back-side interconnect structure 200. Further, the cross-coupling contact 208 may be in the front-side interconnect structure 170.

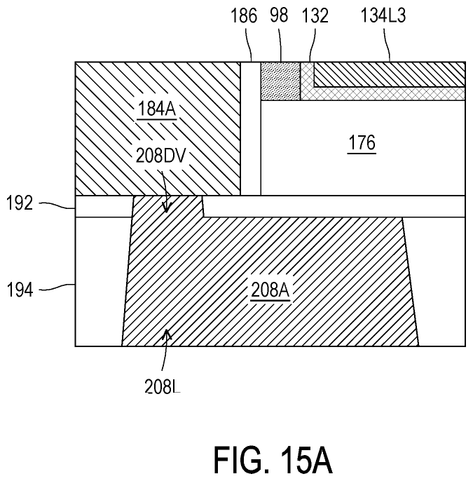

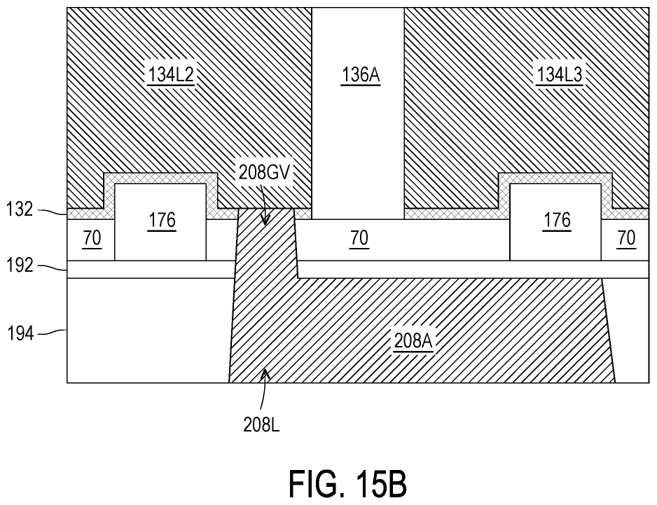

FIGS. 15A-15B are views of a cross-coupling contact 208 for a CFET memory cell, in accordance with some embodiments. Specifically, FIGS. 15A and 15B are detailed views of the first cross-coupling contact 208A of, respectively, FIGS. 14A and 14B. The first cross-coupling contact 208A is formed in the fourth ILD 194. As demonstrated in FIG. 15B, the first cross-coupling contact 208A includes a gate via portion 208GV and a line portion 208L. The gate via portion 208GV extends through the ESL 192, an isolation region 70, and a gate dielectric 132 to contact the second lower gate electrode 134L2. In some embodiments, the gate via portion 208GV is disposed between the first gate isolation region 136A and a dielectric fin 176. The line portion 208L extends along a surface of the ESL 192 and over the first gate isolation region 136A. As demonstrated in FIG. 15A, the first cross-coupling contact 208A may optionally further include a source/drain via portion 208DV that extends through the ESL 192 to contact the first shared source/drain contact 184A. The second cross-coupling contact 208B may be similar to the first cross-coupling contact 208A, except the second cross-coupling contact 208B extends over the second gate isolation region 136B and is coupled to the first lower gate electrode 134L1 and/or the second shared source/drain contact 184B.

The cross-coupling contacts 208 may be formed in a similar manner as the lower gate contacts 196 and the lower source/drain vias 198. Initially, openings for the line portions 208L of the cross-coupling contacts 208 may be formed in the fourth ILD 194. Subsequently, openings for the gate via portions 208GV and/or the source/drain via portions 208DV of the cross-coupling contacts 208 may be formed in the ESL 192, the isolation regions 70, and the gate dielectrics 132. The openings may then be filled with a conductive material and a removal process may be performed, in a similar manner as previously described for FIG. 12.

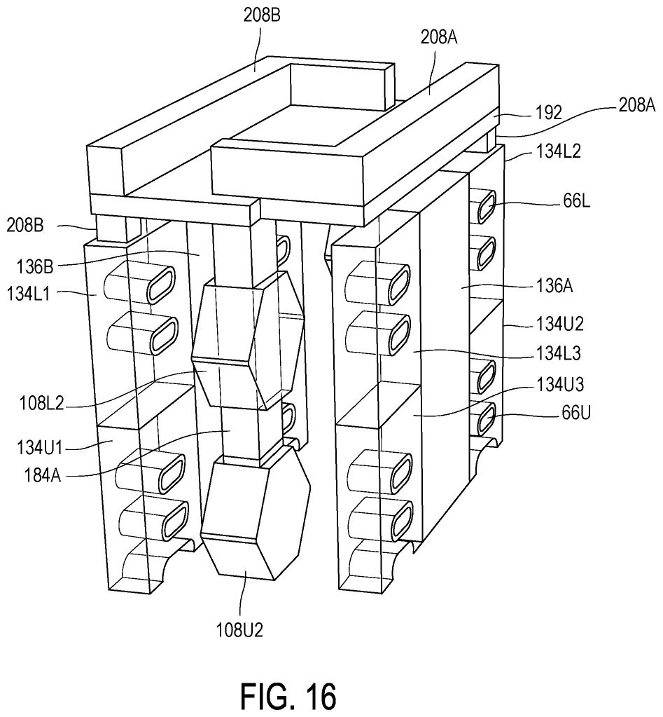

FIG. 16 is a three-dimensional view of a CFET memory cell, in accordance with some embodiments. Specifically, the CFET memory cell of FIGS. 14A-14D is shown, except some features are omitted for illustration clarity. The structure of FIG. 16 is flipped from the previous figures, to more clearly illustrate the cross-coupling contacts 208.

FIGS. 17A-17D are views of a CFET memory cell, in accordance with some embodiments. This embodiment is similar to the embodiment of FIGS. 14A-14D, except the cross-coupling contacts 208 are coupled to respective lower epitaxial source/drain regions 108L through first level conductive lines 204L of the back-side interconnect structure 200. Each cross-coupling contact 208 is I-shaped in a top-down view, where one end of the I-shaped contact is coupled to a lower gate electrode 134L and another end of the I-shaped contact crosses over a gate isolation region 136 to be coupled to a first level conductive line 204L, where the first level conductive line 204L is also coupled to the first shared source/drain contact 184A or the second shared source/drain contact 184B (through a lower source/drain via 198). An I-shaped cross-coupling contact 208 only has a single segment extending in a first direction (e.g., the vertical direction in the top-down views), and the first level conductive line 204L extends in a second direction (e.g., the horizontal direction in the top-down views), where the second direction is perpendicular to the first direction.

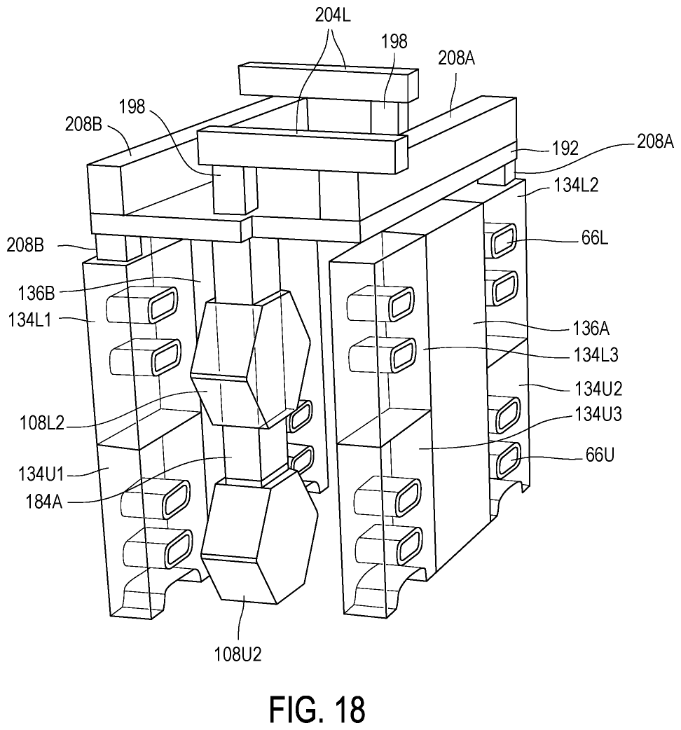

FIG. 18 is a three-dimensional view of a CFET memory cell, in accordance with some embodiments. Specifically, the CFET memory cell of FIGS. 17A-17D is shown, except some features are omitted for illustration clarity. The structure of FIG. 18 is flipped from the previous figures, to more clearly illustrate the cross-coupling contacts 208.

Embodiments may achieve advantages. Because some regions for p-type devices are unused, the first cross-coupling contact 208A and the second cross-coupling contact 208B may overlap the unused p-type regions with a low risk of leakage between the cross-coupling contacts and the features (e.g., the gate electrodes) in those regions. As a result, the inputs and outputs of the cross-coupled inverters may be disposed closer to one another than in other devices. Interconnect complexity may thus be decreased and device scaling may thus be increased.

Other variations are contemplated. For example, the cross-coupling contacts 208 could also be formed to overlap other unused regions (e.g., other unused regions besides those in an SRAM cell footprint).

In an embodiment, a device includes: a first transistor including a first gate structure; a second transistor including a second gate structure, the second gate structure disposed above and coupled to the first gate structure; a third gate structure; a fourth gate structure, the fourth gate structure disposed above and coupled to the third gate structure; a gate isolation region between the first gate structure and the third gate structure, the gate isolation region disposed between the second gate structure and the fourth gate structure; and a cross-coupling contact extending beneath the gate isolation region, the first gate structure, and the third gate structure, the cross-coupling contact coupled to the first gate structure. In some embodiments of the device, the first transistor is a pull-up transistor, the second transistor is a pull-down transistor, the third gate structure is a gate structure extension, and the fourth gate structure is part of a pass-gate transistor. In some embodiments of the device, the first transistor is a pull-down transistor, the second transistor is a pull-up transistor, the third gate structure is part of a pass-gate transistor, and the fourth gate structure is a gate structure extension. In some embodiments of the device, the cross-coupling contact is an L-shaped contact. In some embodiments of the device, the cross-coupling contact is an I-shaped contact. In some embodiments, the device further includes: an isolation region; and a dielectric layer on the isolation region, a line portion of the cross-coupling contact extending along a surface of the dielectric layer, a gate via portion of the cross-coupling contact extending through the dielectric layer and the isolation region to contact the first gate structure. In some embodiments, the device further includes: a back-side interconnect structure beneath the cross-coupling contact, the back-side interconnect structure including a word line interconnect; and a word line contact coupling the word line interconnect to the third gate structure.

In an embodiment, a device includes: a front-side interconnect structure; a back-side interconnect structure; and a device layer between the back-side interconnect structure and the front-side interconnect structure, the device layer including: a first inverter; a second inverter; a first cross-coupling contact connecting a first output of the first inverter to a first input of the second inverter; and a second cross-coupling contact connecting a second output of the second inverter to a second input of the first inverter, the first cross-coupling contact and the second cross-coupling contact each having a first segment that extends in a first direction and along a respective gate electrode of the device layer. In some embodiments of the device: the first inverter includes: a first lower transistor including a first lower source/drain region and a first lower gate structure; and a first upper transistor including a first upper source/drain region and a first upper gate structure, the first upper gate structure physically and electrically coupled to the first lower gate structure; and the second inverter includes: a second lower transistor including a second lower source/drain region and a second lower gate structure; and a second upper transistor including a second upper source/drain region and a second upper gate structure, the second upper gate structure physically and electrically coupled to the second lower gate structure. In some embodiments of the device, the device layer further includes: a first shared source/drain contact coupled to the first lower source/drain region and to the first upper source/drain region, the first cross-coupling contact physically and electrically coupled to the second lower gate structure and the first shared source/drain contact; and a second shared source/drain contact coupled to the second lower source/drain region and to the second upper source/drain region, the second cross-coupling contact physically and electrically coupled to the first lower gate structure and the second shared source/drain contact. In some embodiments of the device, the device layer includes n-type devices stacked over p-type devices, the first cross-coupling contact is disposed at a back-side of the device layer, and the second cross-coupling contact is disposed at the back-side of the device layer. In some embodiments of the device, the device layer includes p-type devices stacked over n-type devices, the first cross-coupling contact is disposed at a front-side of the device layer, and the second cross-coupling contact is disposed at the front-side of the device layer. In some embodiments of the device, the first cross-coupling contact and the second cross-coupling contact each have a second segment that extends in a second direction that is perpendicular to the first direction. In some embodiments of the device, the first segment of the first cross-coupling contact and the second cross-coupling contact is the only segment of the first cross-coupling contact and the second cross-coupling contact.

In an embodiment, a method includes: forming nanostructures above a semiconductor fin, the semiconductor fin extending from an isolation region; forming a lower gate structure, an upper gate structure and a gate isolation region, the lower gate structure wrapped around a lower subset of the nanostructures, the upper gate structure wrapped around an upper subset of the nanostructures, the gate isolation region adjacent the lower gate structure and the upper gate structure; removing a portion of the isolation region; depositing a dielectric layer on a back-side of the isolation region; and forming a cross-coupling contact having a line portion extending along a surface of the dielectric layer and having a gate via portion extending through the dielectric layer and the isolation region to contact the lower gate structure, the line portion crossing beneath the gate isolation region. In some embodiments, the method further includes: growing a lower source/drain region in a recess in the semiconductor fin, the lower gate structure formed adjacent the lower source/drain region; and growing an upper source/drain region in the recess and over the lower source/drain region, the upper gate structure formed adjacent the upper source/drain region. In some embodiments, the method further includes: forming a word line contact extending through the dielectric layer and the isolation region; and forming a back-side interconnect structure below the dielectric layer, the back-side interconnect structure including a word line interconnect coupled to the word line contact. In some embodiments of the method, the lower gate structure includes a gate dielectric and a gate electrode, the gate via portion extending through the gate dielectric to contact the gate electrode. In some embodiments of the method, the cross-coupling contact is L-shaped in a top-down view. In some embodiments of the method, the cross-coupling contact is I-shaped in a top-down view.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
a first transistor comprising a first gate structure;
a second transistor comprising a second gate structure, the second gate structure disposed above and coupled to the first gate structure;
a third gate structure;
a fourth gate structure, the fourth gate structure disposed above and coupled to the third gate structure;
a gate isolation region between the first gate structure and the third gate structure, the gate isolation region disposed between the second gate structure and the fourth gate structure; and
a cross-coupling contact extending beneath the gate isolation region, the first gate structure, and the third gate structure, the cross-coupling contact coupled to the first gate structure.

2. The device of claim 1, wherein the first transistor is a pull-up transistor, the second transistor is a pull-down transistor, the third gate structure is a gate structure extension, and the fourth gate structure is part of a pass-gate transistor.

3. The device of claim 1, wherein the first transistor is a pull-down transistor, the second transistor is a pull-up transistor, the third gate structure is part of a pass-gate transistor, and the fourth gate structure is a gate structure extension.

4. The device of claim 1, wherein the cross-coupling contact is an L-shaped contact.

5. The device of claim 1, wherein the cross-coupling contact is an I-shaped contact.

6. The device of claim 1, further comprising:
an isolation region; and
a dielectric layer on the isolation region, a line portion of the cross-coupling contact extending along a surface of the dielectric layer, a gate via portion of the cross-coupling contact extending through the dielectric layer and the isolation region to contact the first gate structure.

7. The device of claim 1, further comprising:
a back-side interconnect structure beneath the cross-coupling contact, the back-side interconnect structure comprising a word line interconnect; and
a word line contact coupling the word line interconnect to the third gate structure.

8. A device comprising:
a front-side interconnect structure;
a back-side interconnect structure; and
a device layer between the back-side interconnect structure and the front-side interconnect structure, the device layer comprising:
a first inverter;
a second inverter;
a first cross-coupling contact connecting a first output of the first inverter to a first input of the second inverter; and
a second cross-coupling contact connecting a second output of the second inverter to a second input of the first inverter, the first cross-coupling contact and the second cross-coupling contact each having a first segment that extends in a first direction and along a respective gate electrode of the device layer.

9. The device of claim 8, wherein:
the first inverter comprises:
a first lower transistor comprising a first lower source/drain region and a first lower gate structure; and
a first upper transistor comprising a first upper source/drain region and a first upper gate structure, the first upper gate structure physically and electrically coupled to the first lower gate structure; and
the second inverter comprises:
a second lower transistor comprising a second lower source/drain region and a second lower gate structure; and
a second upper transistor comprising a second upper source/drain region and a second upper gate structure, the second upper gate structure physically and electrically coupled to the second lower gate structure.

10. The device of claim 9, wherein the device layer further comprises:
a first shared source/drain contact coupled to the first lower source/drain region and to the first upper source/drain region, the first cross-coupling contact physically and electrically coupled to the second lower gate structure and the first shared source/drain contact; and
a second shared source/drain contact coupled to the second lower source/drain region and to the second upper source/drain region, the second cross-coupling contact physically and electrically coupled to the first lower gate structure and the second shared source/drain contact.

11. The device of claim 8, wherein the device layer comprises n-type devices stacked over p-type devices, the first cross-coupling contact is disposed at a back-side of the device layer, and the second cross-coupling contact is disposed at the back-side of the device layer.

12. The device of claim 8, wherein the device layer comprises p-type devices stacked over n-type devices, the first cross-coupling contact is disposed at a front-side of the device layer, and the second cross-coupling contact is disposed at the front-side of the device layer.

13. The device of claim 8, wherein the first cross-coupling contact and the second cross-coupling contact each have a second segment that extends in a second direction that is perpendicular to the first direction.

14. The device of claim 8, wherein the first segment of the first cross-coupling contact and the second cross-coupling contact is the only segment of the first cross-coupling contact and the second cross-coupling contact.

15. A method comprising:
forming nanostructures above a semiconductor fin, the semiconductor fin extending from an isolation region;
forming a lower gate structure, an upper gate structure and a gate isolation region, the lower gate structure wrapped around a lower subset of the nanostructures, the upper gate structure wrapped around an upper subset of the nanostructures, the gate isolation region adjacent the lower gate structure and the upper gate structure;
removing a portion of the isolation region;
depositing a dielectric layer on a back-side of the isolation region; and
forming a cross-coupling contact having a line portion extending along a surface of the dielectric layer and having a gate via portion extending through the dielectric layer and the isolation region to contact the lower gate structure, the line portion crossing beneath the gate isolation region.

16. The method of claim 15, further comprising:
growing a lower source/drain region in a recess in the semiconductor fin, the lower gate structure formed adjacent the lower source/drain region; and
growing an upper source/drain region in the recess and over the lower source/drain region, the upper gate structure formed adjacent the upper source/drain region.

17. The method of claim 15, further comprising:
forming a word line contact extending through the dielectric layer and the isolation region; and
forming a back-side interconnect structure below the dielectric layer, the back-side interconnect structure comprising a word line interconnect coupled to the word line contact.

18. The method of claim 15, wherein the lower gate structure comprises a gate dielectric and a gate electrode, the gate via portion extending through the gate dielectric to contact the gate electrode.

19. The method of claim 15, wherein the cross-coupling contact is L-shaped in a top-down view.

20. The method of claim 15, wherein the cross-coupling contact is I-shaped in a top-down view.
